(19) United States
(12) Patent Application Publication
(10) Pub. No.: US 2025/0366291 A1
(43) Pub. Date: Nov. 27, 2025

(54) DISPLAY DEVICE AND METHOD FOR MANUFACTURING THE SAME

(71) Applicant: Samsung Display Co., LTD., Yongin-si (KR)

(72) Inventors: In Seok LEE, Yongin-si (KR); Yun Ho LEE, Yongin-si (KR); Min Sik JUNG, Yongin-si (KR); Jeong Hyun JO, Yongin-si (KR); Jae Chil HWANG, Yongin-si (KR)

(21) Appl. No.: 19/040,325

(22) Filed: Jan. 29, 2025

(30) Foreign Application Priority Data
May 27, 2024 (KR) 10-2024-0068283

(51) Int. Cl. H10H 29/41; H10H 29/01

(52) U.S. Cl. CPC H10H 29/41; H10H 29/012

(57) ABSTRACT

A display device includes: a substrate including a first organic film; a plurality of pixel electrodes on the first organic film and aligned in a first direction and a second direction; a common electrode on the first organic film, extending in the first direction, and aligned in the second direction; a plurality of light emitting elements respectively on the pixel electrodes and the common electrode and aligned in the first direction and the second direction; and a second organic film between the light emitting elements on the first organic film. The first organic film has a plurality of engraved lines extending in the first direction and between the light emitting elements, and the plurality of engraved lines are filled with the second organic film.

### CROSS-REFERENCE TO RELATED APPLICATION

The present application claims priority to and the benefit of Korean Patent Application No. 10-2024-0068283, filed on May 27, 2024, in the Korean Intellectual Property Office, the entire disclosure of which is incorporated herein by reference.

### BACKGROUND

### 1. Field

Aspects of embodiments of the present disclosure relate to a display device and a method for manufacturing the same.

### 2. Description of the Related Art

As the information society develops, the demand for display devices for displaying images in various forms is increasing. A display device may be a flat panel display device, such as a liquid crystal display, a field emission display, or a light emitting display, and the like.

A light emitting display device may include an organic light emitting display device including an organic light emitting diode element as a light emitting element, and a micro light emitting display device including a micro light emitting diode element (hereinafter referred to as a micro light emitting diode element) as a light emitting element. Because the micro light emitting diode element is made of inorganic materials, it experiences less deterioration issues and exhibits a longer lifespan compared to organic light emitting diode elements.

Embodiments of the present disclosure provide a display device and a method for manufacturing the same that may easily discharge air bubbles generated when bonding an interposer and a backplane substrate.

However, aspects and features of the present disclosure are not limited to those set forth above. The above and other aspects and features of the present disclosure will become more apparent to one of ordinary skill in the art to which the present disclosure pertains by referencing the detailed description of the present disclosure given below.

According to an embodiment of the present disclosure, display device includes a substrate including a first organic film, a plurality of pixel electrodes on the first organic film and aligned in a first direction and a second direction, a common electrode on the first organic film, extending in the first direction, and aligned in the second direction, a plurality of light emitting elements respectively on the pixel electrodes and the common electrode and aligned in the first direction and the second direction, and a second organic film between the light emitting elements on the first organic film. The first organic film has a plurality of engraved lines extending in the first direction and arranged between the light emitting elements, and the plurality of engraved lines are filled with the second organic film.

The plurality of engraved lines may be below the light emitting elements.

A width of the plurality of engraved lines may be greater than a depth of the plurality of engraved lines.

The plurality of engraved lines may have a cross-sectional shape of one of: a right rectangle, an inverted triangle, an inverted trapezoid, and a semicircle.

Each of the plurality of engraved lines may have the same width.

A width of one engraved lines may become wider as the engraved line is nearer to an outer side of the substrate from a center of the substrate.

Each of the plurality of engraved lines may become wider from a center thereof to an outside thereof.

The light emitting element may include a semiconductor stack, a first contact electrode between one surface of the semiconductor stack and the pixel electrode, and a second contact electrode between one surface of the semiconductor stack and the common electrode.

The second organic film may be arranged between the light emitting elements to flatten a step difference between the light emitting elements.

According to an embodiment of the present disclosure, a method of manufacturing a display device include patterning an adhesive layer applied on an interposer into first areas and second areas; patterning a plurality of engraved lines on a backplane mother substrate comprising a plurality of cell regions; arranging the first areas of the interposer and the cell region of the backplane mother substrate to overlap; and bonding a plurality of light emitting elements to the first area of the interposer such that the engraved line is between adjacent ones of the plurality of light emitting elements.

The patterning of the adhesive layer may include one of: removing the adhesive layer from the second areas, thinning a thickness of the adhesive layer from the second areas, and reducing an adhesive component of the adhesive layer in the second areas.

The method may further include, before the bonding of the plurality of light emitting elements, disposing a plurality of light emitting elements into the first areas of the interposer.

The first area may have a size and area corresponding to a cell area of the backplane mother substrate.

The method may further include, before the bonding of the plurality of light emitting elements: forming a main alignment mark in an area adjacent to a vertex within the interposer; and forming a sub-alignment mark in another area adjacent to each vertex of the first areas.

The bonding of the plurality of light emitting elements may include: aligning the interposer on a backplane mother substrate by using the main alignment mark; and transferring the plurality of light emitting element from the interposer onto a cell area of the backplane mother substrate by using the sub-alignment mark.

The patterning of the plurality of engraved lines may include patterning a plurality of engraved lines in a cell area of the backplane mother substrate by using a halftone mask.

A bubble layer generated when the interposer is bonded to the backplane mother substrate may be discharged along at least one of the plurality of engraved lines.

The method may further include: transferring the plurality of light emitting elements on the interposer to the backplane mother substrate; and forming an organic film layer to flatten a step difference formed by the plurality of light emitting elements and filling the plurality of engraved lines with the organic film layer.

According to an embodiment of the present disclosure, a display device includes a substrate including a first organic film, a plurality of pixel electrodes on the first organic film, a plurality of light emitting elements respectively on the pixel electrodes, a second organic film between the light emitting elements on the first organic film, and a common electrode on the light emitting elements and the second organic film. The first organic film has a plurality of engraved lines extending in the first direction and arranged between the light emitting elements, and the plurality of engraved lines are filled with the second organic film.

According to an embodiment of the present disclosure, a wearable device includes a display device. The display device includes: a substrate including a first organic film; a plurality of pixel electrodes on the first organic film and aligned in a first direction and a second direction; a common electrode on the first organic film, extending in the first direction, and aligned in the second direction; a light emitting element on the pixel electrode and the common electrode and aligned in the first direction and the second direction; and a second organic film between the light emitting elements on the first organic film. The first organic film of the display device has a plurality of engraved lines extending in the first direction and between the light emitting elements, and the plurality of engraved lines of the display device are filled with the second organic film.

According to embodiments of the display device and the manufacturing method thereof, air bubbles generated when the interposer and the backplane substrate are bonded may be easily discharged.

However, the aspects and features of the present disclosure are not limited to the aforementioned aspects and features, and various other aspects and features are included in the present specification.

### BRIEF DESCRIPTION OF THE DRAWINGS

These and/or other aspects and features of the present disclosure will become apparent and more readily appreciated from the following description of the embodiments, taken in conjunction with the accompanying drawings, in which:

FIG. 1 is a perspective view of a display device according to an embodiment.

FIG. 2 is a layout diagram illustrating a display device according to one embodiment.

FIG. 3 is a block diagram schematically illustrating a display device according to one embodiment.

FIG. 4 is an equivalent circuit diagram illustrating a sub-pixel according to one embodiment.

FIG. 5 is a layout diagram schematically illustrating pixels in a display area according to one embodiment.

FIG. 6 is a cross-sectional view of a display panel taken along the line I-I′ in FIG. 5.

FIG. 7 is a cross-sectional view of the area A of FIG. 6.

FIG. 8 is a perspective view illustrating a light emitting element, pixel electrode layer, and engraved line shown in FIG. 5.

FIG. 9 is a cross-sectional view of the area A of FIG. 6 according to another embodiment.

FIGS. 10 and 11 are cross-sectional views of the area A of FIG. 6 according to other embodiments.

FIGS. 12 and 13 are cross-sectional views of the area A in FIG. 6 according to other embodiments.

FIGS. 14 to 16 are schematic layout views of a plurality of engraved lines according to one embodiment.

FIG. 17 is a flowchart describing a method of manufacturing a display device according to one embodiment.

FIGS. 18 to 22 are schematic diagrams illustrating steps of a method of manufacturing a display device according to one embodiment.

FIG. 23 is a layout diagram illustrating pixels of a display area according to another embodiment.

FIG. 24 is a cross-sectional view of a display panel corresponding to the lines II-II′ in FIG. 23.

FIG. 25 is a cross-sectional view of the area A in FIG. 23.

FIG. 26 is a perspective view of a smart watch including a display device according to an embodiment;

FIGS. 27 and 28 are a perspective view and an exploded perspective view, respectively, of a virtual reality (VR) device including a display device according to an embodiment;

FIG. 29 is a perspective view of a VR device including a display device according to an embodiment;

FIG. 30 is a view of a vehicle instrument cluster and center fascia including display devices according to an embodiment; and

FIG. 31 is a view of a transparent display device including a display device according to an embodiment.

### DETAILED DESCRIPTION

Embodiments of the present disclosure will now be described more fully hereinafter with reference to the accompanying drawings. These embodiments, and the present disclosure, may, however, be provided in different forms, and the present disclosure should not be construed as limited to the illustrated embodiments. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

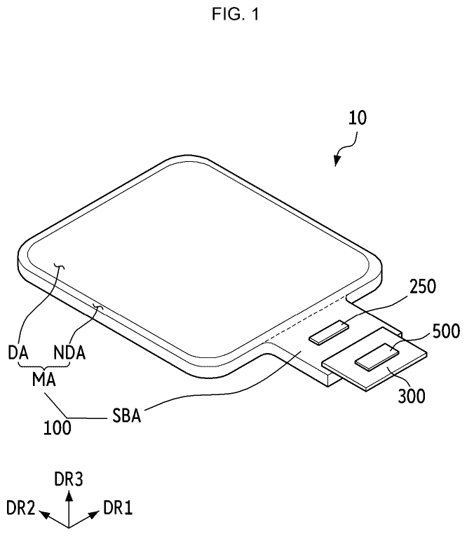

FIG. 1 is a perspective view of a display device 10 according to an embodiment.

Referring to FIG. 1, the display device 10 is a device for displaying moving images and/or still images. The display device 10 may be used as a display screen in portable electronic devices, such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various other products, such as televisions, notebook computers, monitors, billboards, and Internet of things (IoT) devices.

The display device 10 may be a light emitting display, such as an organic light emitting display using an organic light emitting diode, a quantum dot light emitting display including a quantum dot light emitting layer, an inorganic light emitting display including an inorganic semiconductor, or a micro- or nano-light emitting display using a micro- or nano-light emitting diode (LED). An embodiment in which the display device 10 is a micro- or nano-light emitting display will be primarily described below, but the present disclosure is not limited thereto. For ease of description, a micro- or nano-LED will be referred to as a light emitting element.

The display device 10 includes a display panel 100, a display driving circuit 250, a circuit board 300, and a power supply unit 500.

The display panel 100 may have a rectangular plane shape having short sides in (e.g., extending in) a first direction DR1 and long sides in (e.g., extending in) a second direction DR2 crossing (e.g., intersecting) the first direction DR1. Each corner at where a short side extending in the first direction DR1 meets a long side extending in the second direction DR2 may be rounded to have a curvature (e.g., a predetermined curvature) or may be right-angled. The planar shape of the display panel 100 is not limited to a quadrangular shape but may be other polygonal shapes, a circular shape, or an elliptical shape. The display panel 100 may be flat, but embodiments are not limited thereto. For example, the display panel 100 may have a curved portion formed at left and/or right ends and having a constant or varying curvature. In addition, the display panel 100 may be formed to be flexible so that it can be curved, bent, folded, and/or rolled.

A substrate SUB of the display panel 100 may have a main area MA and a sub-area SBA.

The main area MA may include a display area DA at where an image is displayed and a non-display area NDA disposed around (e.g., extending around) the display area DA. The display area DA may include a plurality of pixels which display an image. Each of the pixels may include a plurality of subpixels. For example, each of the pixels may include a first subpixel that emits light of a first color, a second subpixel that emits light of a second color, and a third subpixel which that light of a third color, but embodiments of the present disclosure are not limited thereto.

The sub-area SBA may protrude from a side of the main area MA in the second direction DR2. Although the sub-area SBA is shown in an unfolded state in FIG. 1, it may be bent. In this case, the sub-area SBA may be placed on a lower surface of the display panel 100. When the sub-area SBA is bent, it may overlap the main area MA in a third direction DR3, which is a thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit and attached onto the display panel 100 by using a chip on glass (COG) method, a chip on plastic (COP) method, or an ultrasonic bonding method. However, embodiments are not limited thereto. For example, the display driving circuit 250 may also be attached onto the circuit board 300 using a chip on film (COF) method.

The circuit board 300 may be attached to an end of the sub-area SBA of the display panel 100. Accordingly, the circuit board 300 may be electrically connected to the display panel 100 and the display driving circuit 250. The display panel 100 and the display driving circuit 250 may receive digital video data, timing signals, and driving voltages through the circuit board 300. The circuit board 300 may be a flexible printed circuit board, a printed circuit board, or a flexible film, such as a chip on film.

The power supply unit 500 may generate a plurality of panel driving voltages according to a power supply voltage received from the outside. The power supply unit 500 may be formed as an integrated circuit and attached onto the circuit board 300 by using a COF method.

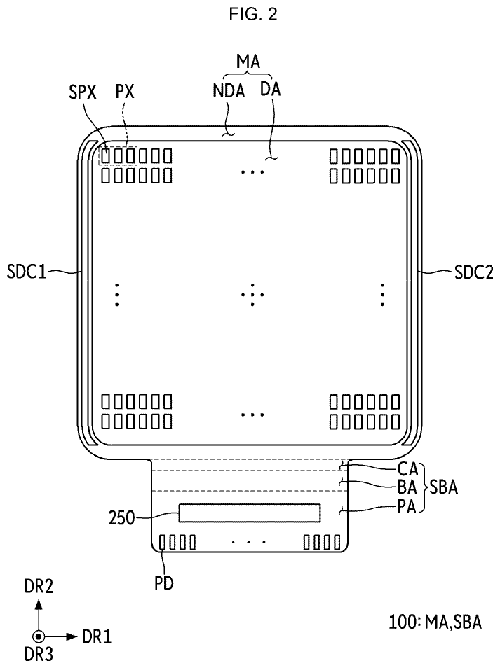

FIG. 2 is a layout diagram of a display device according to one embodiment. FIG. 2 illustrates the sub-area SBA in an unfolded state (e.g., without being bent).

Referring to FIG. 2, the display panel 100 may have the main area MA and the sub-area SBA.

The main area MA may include the display area DA at where an image is displayed and the non-display area NDA, which is a peripheral area of (e.g., around) the display area DA. The display area DA may occupy most of the main area MA. The display area DA may be arranged in the center of the main area MA.

The display area DA may include a plurality of pixels PX for displaying an image, and each of the plurality of pixels PX may include a plurality of sub-pixels SPX. A pixel PX may be defined as a sub-pixel group of the smallest unit capable of expressing a white grayscale.

The non-display area NDA may be adjacent to the display area DA. The non-display area NDA may be an area outside the display area DA. The non-display area NDA may be arranged to surround (e.g., to surround or extend around a periphery of) the display area DA. The non-display area NDA may be an edge area of the display panel 100.

A plurality of engraved lines AOL may be arranged in the main area MA. Each of the plurality of engraved lines AOL may extend in the first direction DR1 and may be arranged in (e.g., may be adjacent to each other in) the second direction DR2. For example, the plurality of engraved lines AOL may extend from one end to the other end in the first direction DR1 of the display panel 100 at a constant depth and may be uninterrupted. Each of the plurality of engraved lines AOL may be disposed between the sub-pixels SPX at equal intervals, but the present disclosure is not limited thereto.

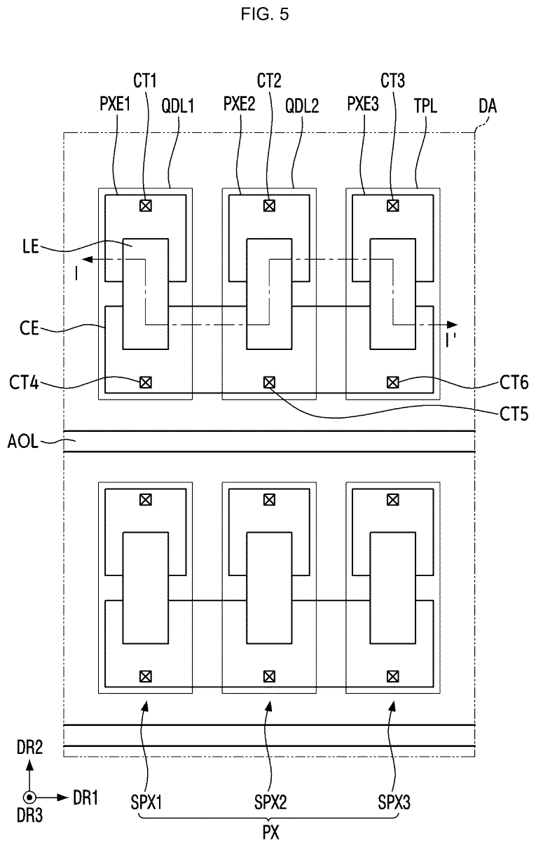

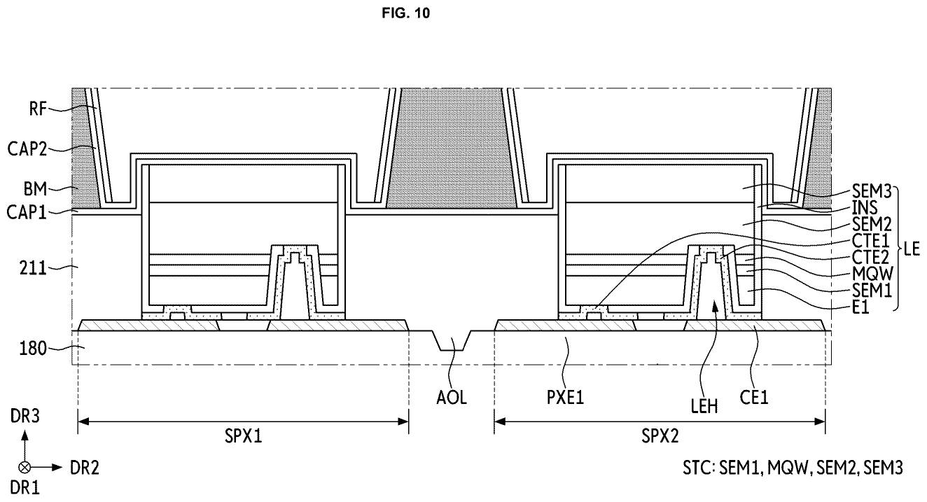

The shape and arrangement of the plurality of engraved lines AOL will be described in more detail later with reference to FIGS. 5 to 16.

A first scan driving unit SDC1 and a second scan driving unit SDC2 may be disposed in the non-display area NDA. The first scan driving unit SDC1 is disposed on one side (e.g., the left side) of the display panel 100, and the second scan driving unit SDC2 is disposed on the other side (e.g., the right side) of the display panel 100. However, embodiments are not limited thereto. Each of the first scan driving unit SDC1 and the second scan driving unit SDC2 may be electrically connected to the display driving circuit 250 through scan fan-out lines. Each of the first scan driving unit SDC1 and the second scan driving unit SDC2 may receive a scan control signal from the display driving circuit 250, generate scan signals according to the scan control signal, and output them to the scan lines.

The sub-area SBA may protrude from one side of the main area MA in the second direction DR2. The length of the sub-area SBA in the second direction DR2 may be smaller than the length of the main area MA in the second direction DR2. The length of the first direction DR1 of the sub-area SBA is smaller than the length of the first direction DR1 of the main area MA or may be substantially equal to the length of the first direction DR1 of the main area MA. The sub-area SBA may be curved and may be disposed at the lower portion of the display panel 100. In this case, the sub-area SBA may overlap the main area MA in the third direction DR3.

The sub-area SBA may have a connection area CA, a pad area PA, and a bending area BA.

The connection area CA is an area protruding from one side of the main area MA in the second direction DR2. One side of the connection area CA may be in contact with the non-display area NDA of the main area MA, and the other side of the connection area CA may be in contact with the bending area BA.

The pad area PA is an area at where the pads PD and the display driving circuit 250 are disposed. The display driving circuit 250 may be attached to the driving pads of the pad area PA by using a conductive adhesive member, such as an anisotropic conductive film. The circuit board 300 may be attached to the pads PD of the pad area PA by using a conductive adhesive member, such as an anisotropic conductive film. One side of the pad area PA may be in contact with the bending area BA.

The bending area BA is a bent area (e.g., is an area that is designed to be bent). When the bending area BA is bent, the pad area PA may be disposed below the connection area CA and below the main area MA. The bending area BA may be disposed between the connection area CA and the pad area PA. One side of the bending area BA may be in contact with the connection area CA, and the other side of the bending area BA may be in contact with the pad area PA.

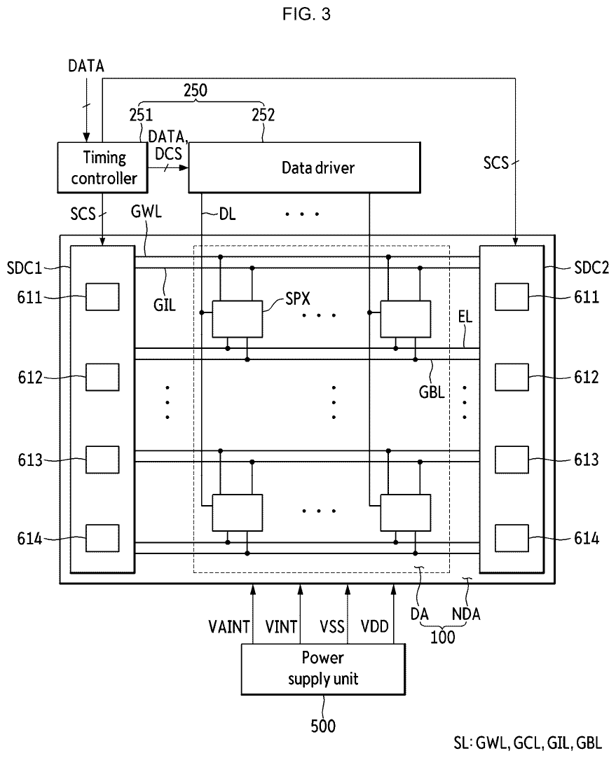

FIG. 3 is a block diagram schematically illustrating a display device according to one embodiment.

Referring to FIG. 3, the display area DA includes a plurality of pixels PX, a plurality of scan lines SL, a plurality of emission control lines EL, and a plurality of data lines DL.

The plurality of pixels PX may be arranged in a matrix form in the first direction DR1 and the second direction DR2. The plurality of scan lines SL and the plurality of emission control lines EL may extend in the first direction DR1 and may be disposed in (e.g., arranged in) the second direction DR2. The plurality of data lines DL may extend in the second direction DR2 and may be disposed in the first direction DR1. The plurality of scan lines SL may include a plurality of write scan lines GWL, a plurality of control scan lines GCL, a plurality of initialization scan lines GIL, and a plurality of bias scan lines GBL.

Each of the plurality of sub-pixels SPX may be connected to a write scan line GWL from among the plurality of write scan lines GWL, a control scan line GCL from among the plurality of control scan lines GCL, an initialization scan line GIL from among the plurality of initialization scan lines GIL, a bias scan line GBL from among the plurality of bias scan lines GBL, an emission control line EL from among the plurality of emission control lines EL, and a data line DL from among the plurality of data lines DL. Each of the plurality of sub-pixels SPX may be supplied with a data voltage of the data line DL according to the write scan signal of the write scan line GWL and may emit light emitting elements according to the data voltage.

The non-display area NDA includes a first scan driving unit SDC1, a second scan driving unit SDC2, and a display driving circuit 250.

Each of the first scan driving portion SDC1 and the second scan driving portion SDC2 may include a write scan signal output portion 611, an initialization scan signal output portion 612, a bias scan signal output portion 613, and a light emission control signal output portion 614. Each of the write scan signal output portion 611, the initialization scan signal output portion 612, the bias scan signal output portion 613, and the light emission control signal output portion 614 may receive a scan timing control signal SCS from a timing control circuit 251.

The write scan signal output portion 611 may generate the write scan signals according to the scan timing control signal SCS of the timing control circuit 251 and sequentially output them to the write scan lines GWL.

The initialization scan signal output portion 612 may generate initialization scan signals according to the scan timing control signal SCS and sequentially output them to the initialization scan lines GIL.

The bias scan signal output portion 613 may generate bias scan signals according to the scan timing control signal SCS and sequentially output them to the bias scan lines GBL. The light emission control signal output portion 614 may generate emission control signals according to the scan timing control signal SCS and sequentially output them to the emission control lines EL.

The display driving circuit 250 includes a timing control circuit 251 and a data driving circuit 252.

The data driving circuit 252 may receive digital video data DATA and a data timing control signal DCS from the timing control circuit 251. The data driving circuit 252 converts digital video data DATA into analog data voltages according to the data timing control signal DCS and outputs them to the data lines DL. In the illustrated embodiment, the sub-pixels SPX are selected by the write scan signals of the first scan driving unit SDC1 and the second scan driving unit SDC2, and data voltages may be supplied to the selected sub-pixels SPX.

The timing control circuit 251 may receive digital video data DATA and timing signals from an external source. The timing control circuit 251 may generate the scan timing control signal SCS and the data timing control signal DCS to control the display panel 100 according to timing signals. The timing control circuit 400 may output the scan timing control signal SCS to the first scan driving unit SDC1 and the second scan driving unit SDC2. The timing control circuit 251 may output digital video data DATA and a data timing control signal DCS to the data driving circuit 252.

The power supply unit 500 may generate a plurality of panel driving voltages according to an external power supply voltage. For example, the power supply unit 500 may generate and supply a first power supply voltage VDD, a second power supply voltage VSS, a third power supply voltage VINT, and a fourth power supply voltage VAINT to the display panel 100.

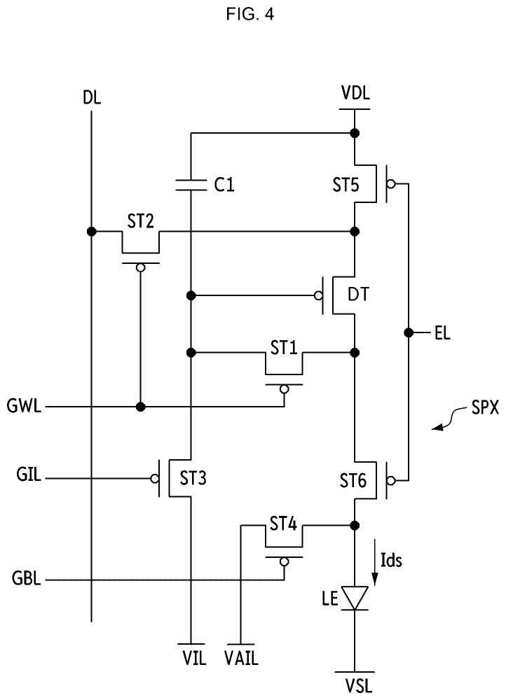

FIG. 4 is an equivalent circuit diagram illustrating a sub-pixel according to one embodiment.

Referring to FIG. 4, the sub-pixel SPX according to one embodiment may be connected to scan lines GWL, GIL, and GBL, an emission control line EL, and a data line DL. For example, the sub-pixel SPX1 may be connected to a write scan line GWL, an initialization scan line GIL, a bias scan line GBL, an emission control line EL, and a data line DL.

The sub-pixel SPX according to one embodiment includes a driving transistor DT, switch elements, a capacitor C1, and a light emitting element LE. The switch elements include first to sixth transistors ST1, ST2, ST3, ST4, ST5, and ST6.

The driving transistor DT includes a gate electrode, a first electrode, and a second electrode. The driving transistor DT controls the drain-source current (Ids, hereinafter referred to as “driving current”) flowing between the first electrode and the second electrode according to the data voltage applied to the gate electrode.

The light emitting element LE may be a micro light emitting diode.

The light emitting element LE emits light according to the driving current Ids. The amount of light emitted from the light emitting element LE may be proportional to the driving current Ids. The anode electrode of the light emitting element LE is connected to the first electrode of the fourth transistor ST4 and the second electrode of the sixth transistor ST6, and the cathode electrode may be connected to a second power supply line VSL to which a second power supply voltage is applied.

The capacitor C1 is formed between the gate electrode of the driving transistor DT and the first power supply line VDL to which the first power supply voltage is applied. The first power supply voltage may be at a higher level than the second power supply voltage. One electrode of the capacitor C1 may be connected to the gate electrode of the driving transistor DT, and the other electrode thereof may be connected to the first power supply line VDL.

As shown in FIG. 4, the first to sixth transistors ST1, ST2, ST3, ST4, ST5, and ST6 and the driving transistor DT may all be formed as p-type MOSFETs. In such an embodiment, the active layer of each of the first to sixth transistors ST1, ST2, ST3, ST4, ST5, and ST6 and the driving transistor DT may be formed of polysilicon.

The gate electrode of the first transistor ST1 and the gate electrode of the second transistor ST2 may be connected to the write scan line GWL, the gate electrode of the third transistor ST3 may be connected to the initialization scan line GIL, and the gate electrode of the fourth transistor ST4 may be connected to the bias scan line GBL. Because the first to sixth transistors ST1, ST2, ST3, ST4, ST5, and ST6 are formed as p-type MOSFET, they may be turned on when the initialization scan line GIL, the write scan line GWL, the bias scan line GBL, and the emission line EL are applied with a scan signal having a gate low voltage and an emission control signal, respectively. One electrode of the third transistor ST3 may be connected to the first initialization voltage line VIL to which the third power supply voltage (e.g., VINT in FIG. 3) is applied, and one electrode of the fourth transistor ST4 may be connected to the second initialization voltage line VAIL to which the fourth power supply voltage (e.g., VAINT in FIG. 3) is applied. The third power supply voltage (e.g., VINT in FIG. 3) and the fourth power supply voltage (e.g., VAINT in FIG. 3) may be different voltages. Also, the third power supply voltage (e.g., VINT in FIG. 3) and the fourth power supply voltage (e.g., VAINT in FIG. 3) may be a voltage at a lower level than the first power supply voltage VDD and a voltage at a higher level than the second power supply voltage VSS.

In another embodiment, the driving transistor DT, the second transistor ST2, the fourth transistor ST4, the fifth transistor ST5, and the sixth transistor ST6 may be formed of p-type MOSFETs, and the first transistor ST1 and the third transistor ST3 may be formed of n-type MOSFETs. In such an embodiment, the active layer of each of the driving transistor DT, the second transistor ST2, the fourth transistor ST4, the fifth transistor ST5, and the sixth transistor ST6 formed of a p-type MOSFET may be formed of polysilicon, and the active layer of each of the first and third transistors ST1 and ST3 formed as an n-type MOSFET may be formed of an oxide semiconductor. Further, because the first transistor ST1 and the third transistor ST3 are formed as n-type MOSFETs, the first transistor ST1 may be turned on when a scan signal having a gate high voltage is applied, and the third transistor ST3 may be turned on when an initialization scan signal having the gate high voltage is applied. In comparison, the second transistor ST2, the fourth transistor ST4, the fifth transistor ST5, and the sixth transistor ST6 are formed as p-type MOSFETs, so they may be turned on when a scan signal having the gate low voltage and a light emission control signal are applied.

In another embodiment, if the fourth transistor ST4 is formed as an n-type MOSFET and the remaining transistors DT, ST1, ST2, ST3, ST5, and ST6 are formed as p-type MOSFETs, the active layer of the fourth transistor ST4 may be formed as an oxide semiconductor, and the active layer of each of the remaining transistors DT, ST1, ST2, ST3, ST5, and ST6 may be formed as polysilicon. Further, the fourth transistor ST4 may be turned on when a scan signal having a gate high voltage is applied, while the remaining transistors DT, ST1, ST2, ST3, ST5, and ST6 may be turned on when a scan signal having a gate low voltage and a light emission control signal are applied.

In another embodiment, the first to sixth transistors ST1, ST2, ST3, ST4, ST5, and ST6 and the driving transistor DT may all be formed as n-type MOSFETs. In such an embodiment, the active layer of each of the first to sixth transistors ST1, ST2, ST3, ST4, ST5, and ST6 and the driving transistor DT is formed of an oxide semiconductor and may be turned on when a scan signal having the gate high voltage and a light emission control signal are applied.

FIG. 5 is a layout diagram illustrating pixels in a display area according to one embodiment.

Referring to FIG. 5, each of the plurality of pixels PX of the display area DA may include three sub-pixels SPX1, SPX2, and SPX3, but embodiments of the present disclosure are not limited thereto and may include, for example, four sub-pixels.

The plurality of pixels PX may be arranged in a matrix form. In each of the plurality of pixels PX, the first sub-pixel SPX1, the second sub-pixel SPX2, and the third sub-pixel SPX3 may be arranged in (e.g., may be adjacent to each other in) a first direction DR1.

When each of the plurality of pixels PX includes three sub-pixels SPX1, SPX2, and SPX3, the first sub-pixel SPX1 may emit light of a first color, and the second sub-pixel SPX2 may emit light of a second color, and the third sub-pixel SPX3 may emit light of a third color. Here, the first color light may be light in a blue wavelength band, the second color light may be light in a green wavelength band, and the third color light may be light in a red wavelength band. For example, the blue wavelength band may refer to light having a main peak wavelength in a wavelength band from approximately 370 nm to approximately 460 nm, the green wavelength band may refer to light having a main peak wavelength in a wavelength band from approximately 480 nm to approximately 560 nm, and the red wavelength band may refer to light having a main peak wavelength in a wavelength band from approximately 600 nm to approximately 750 nm.

In another embodiment, when each of the plurality of pixels PX includes four sub-pixels, the first sub-pixel may emit light of a first color, the second and fourth sub-pixels may emit light of a second color, and the third sub-pixel may emit light of a third color. In another embodiment, the first sub-pixel may emit light of a first color, the second sub-pixel may emit light of a second color, the third sub-pixel may emit light of a third color, and the fourth sub-pixel may emit light of a fourth color. In such an embodiment, the fourth color light may be white light.

The first sub-pixel SPX1 includes a first pixel electrode PXE1, a light emitting element LE, and a first light conversion layer QDL1. The second sub-pixel SPX2 includes a second pixel electrode PXE2, a light emitting element LE, and a second light conversion layer QDL2. The third sub-pixel SPX3 includes a third pixel electrode PXE3, a light emitting element LE, and a third light conversion layer QDL3. Additionally, the first sub-pixel SPX1, the second sub-pixel SPX2, and the third sub-pixel SPX3 may include a common electrode CE. The common electrode CE may extend in the first direction DR1.

In each of the first sub-pixel SPX1, the second sub-pixel SPX2, and the third sub-pixel SPX3, the pixel electrodes PXE1, PXE2, and PXE3 and the common electrode CE may be arranged in the second direction DR2. Each of the pixel electrodes PXE1, PXE2, and PXE3 and the common electrode CE may have a rectangular planar shape, but embodiments of the present disclosure are not limited thereto.

As shown in FIG. 5, the areas of the first light conversion layer QDL1, the second light conversion layer QDL2, and the third light conversion layer QDL3 may all be the same, but they are not limited thereto. For example, when the light conversion efficiency of the second light conversion layer QDL2 is lower than the light conversion efficiency of the first light conversion layer QDL1, the area of the second pixel electrode PXE2 may be larger than the area of the first pixel electrode PXE1. Also, while the light transmission layer TPL transmits the light of the light emitting element LE as is (e.g., without conversion), so the area of the first pixel electrode PXE1 may be larger than the area of the third pixel electrode PXE3 for the first light conversion layer QDL1 to convert the light.

Each of the pixel electrodes PXE1, PXE2, and PXE3 may be electrically connected to at least one transistor through a pixel connection hole (e.g., a pixel connection opening) CT1, CT2, and CT3. For example, each of the pixel electrodes PXE1, PXE2, and PXE3 may be electrically connected to the second electrode of the fourth transistor (e.g., ST4 in FIG. 4) and the second electrode of the sixth transistor (e.g., ST6 in FIG. 4) of the corresponding sub-pixel.

The common electrode CE may be connected to the second power supply line VSL to which a second driving voltage VSS is applied through a first common connection hole (e.g., a first common connection opening) CT4. Therefore, the second driving voltage VSS may be applied to each of the common electrodes CE. The pixel electrodes PXE1, PXE2, and PXE3 may be referred to as an anode electrode or a first electrode, and the common electrode CE may be referred to as a cathode electrode or a second electrode.

The plurality of light emitting elements LE may be disposed on the pixel electrodes PXE1, PXE2, and PXE3 and the common electrode CE. Each of the plurality of light emitting elements LE may have a circular planar shape, but embodiments of the present disclosure are not limited thereto. For example, each of the plurality of light emitting elements LE may have a rectangular planar shape.

The plurality of engraved lines AOL may extend in the first direction DR1. For example, the engraved line AOL may be disposed parallel to the extension direction of the common electrode CE. The plurality of engraved lines AOL are arranged at equal (or regular) intervals in the second direction DR2. The plurality of engraved lines AOL provide a path through which air that may be generated during the bonding process may escape.

The first light conversion layer QDL1 may completely (or entirely) overlap the plurality of light emitting element LE of the first sub-pixel SPX1. The first light conversion layer QDL1 may convert or shift the peak wavelength of incident light into light of another specific peak wavelength and emit it. For example, the first light conversion layer QDL1 may convert or shift the third light emitted from the plurality of light emitting elements LE of the first sub-pixel SPX1 into the first light.

The second light conversion layer QDL2 may completely (or entirely) overlap the plurality of light emitting element LE of the second sub-pixel SPX2. The second light conversion layer QDL2 may convert or shift the peak wavelength of incident light into light of another specific peak wavelength and emit it. For example, the second light conversion layer QDL2 may convert or shift the third light emitted from the plurality of light emitting elements LE of the second sub-pixel SPX2 into the second light.

The light transmission layer TPL may completely (or entirely) overlap the plurality of light emitting element LE of the third sub-pixel SPX3. The light transmission layer TPL may transmit incident light as it is. For example, the light transmission layer TPL may directly transmit the third light emitted from the plurality of light emitting elements LE of the third sub-pixel SPX3.

When the light emitting element LE of the first sub-pixel SPX1 emits light of a first color, the light emitting element LE of the second sub-pixel SPX2 emits light of a second color, and the light emitting element LE of the third sub-pixel SPX3 emits light of a third color, the light conversion layers QDL1 and QDL2 and the light transmission layer TPL may be omitted.

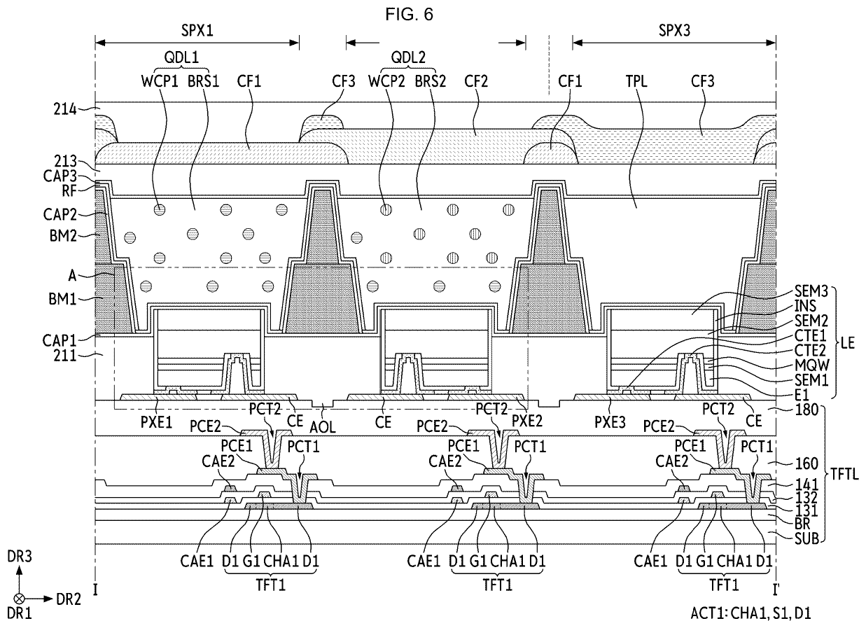

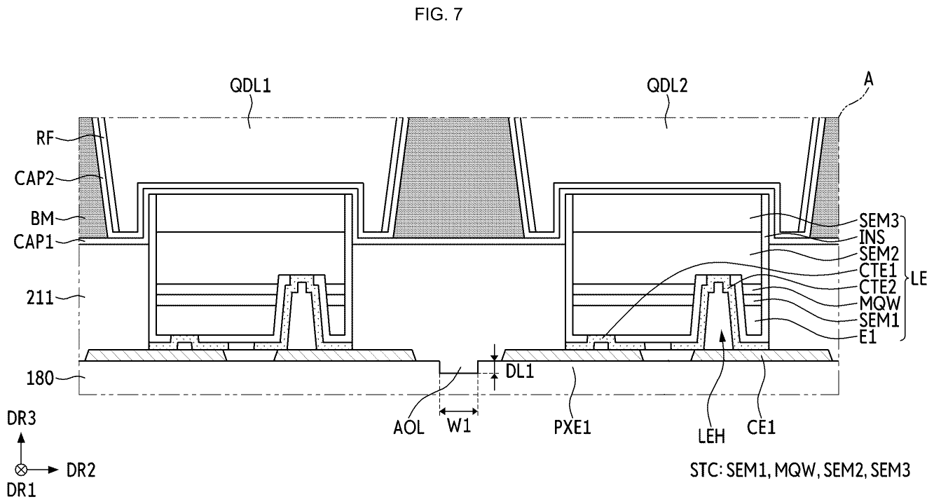

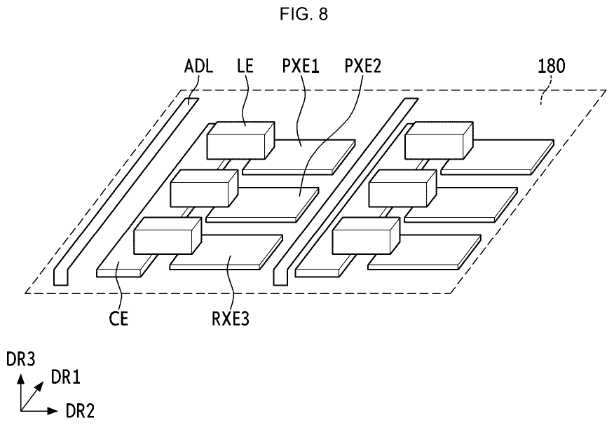

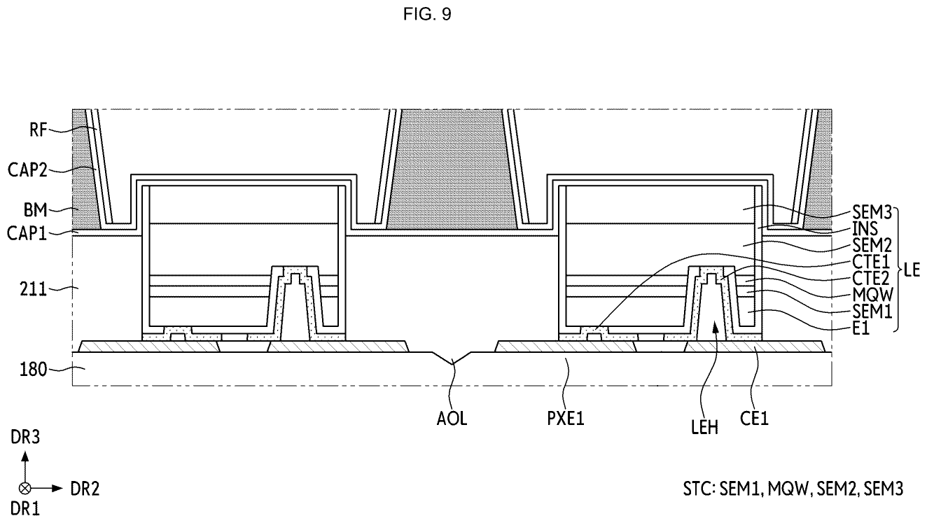

FIG. 6 is a cross-sectional view of a display panel taken along the line I-I′ in FIG. 5. FIG. 7 is a cross-sectional view of the area A of FIG. 6. FIG. 8 is a perspective view illustrating the light emitting element, pixel electrode layer, and engraved line shown in FIG. 5. FIG. 9 is a detailed cross-sectional view illustrating the area A of FIG. 6 according to another embodiment.

Referring to FIGS. 6 to 8, a substrate SUB may be made of an insulating material, such as glass, polymer resin, or the like. If the substrate SUB is made of polymer resin, it may be a flexible substrate that may be stretched. The polymer resin may be acrylic resin, epoxy resin, phenolic resin, polyamide resin, polyimide resin, or the like.

A barrier film BR may be disposed on the substrate SUB. The barrier film BR is a film that protects the transistors in the thin film transistor layer TFTL from moisture penetrating through the substrate SUB, which is vulnerable to moisture penetration. The barrier film BR may include (or may be composed of) a plurality of alternately stacked inorganic films.

A thin film transistor TFT1 may be disposed on the barrier film BR. The thin film transistor TFT1 may be either the fourth transistor ST4 or the sixth transistor ST6 as shown in, for example, FIG. 4. The thin film transistor TFT1 may include a first active layer ACT1 and a first gate electrode G1.

The first active layer ACT1 of the thin film transistor TFT1 may be disposed on the barrier film BR. The first active layer ACT1 of the thin film transistor TFT1 may include polycrystalline silicon, monocrystalline silicon, low-temperature polycrystalline silicon, or amorphous silicon. In another embodiment, the first active layer ACT1 of the thin film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), or IGTO (indium (In), gallium (Ga), tin (Sn), and oxygen (O)).

The first active layer ACT1 may have a first channel area CHA1, a first source area S1, and a first drain area D1. The first channel area CHA1 may be an area overlapping the first gate electrode G1 in the third direction DR3, which is the thickness direction of the substrate SUB. The first source area S1 may be disposed on one side of the first channel area CHA1, and the first drain area D1 may be disposed on the other side of the first channel area CHA1. The first source area S1 and the first drain area D1 may be areas that do not overlap the first gate electrode G1 in the third direction DR3. The first source area S1 and the first drain area D1 may be conductive areas in which semiconductor materials are doped with ions.

A first gate insulating film 131 may be disposed on the first channel area CHA1, the first source area S1, and the first drain area D1 of the thin film transistor TFT1.

A first gate metal layer may be disposed on a first gate insulating film 131. The first gate metal layer may include the first gate electrode G1 and the first capacitor electrode CAE1 of the thin film transistor TFT1. The first gate electrode G1 may overlap the first active layer ACT1 in the third direction DR3. In FIG. 6, the first gate electrode G1 and the first capacitor electrode CAE1 are shown as being disposed apart from each other, but the first gate electrode G1 and the first capacitor electrode CAE1 may be connected to each other.

A second gate insulating film 132 may be disposed on the first gate electrode G1 and the first capacitor electrode CAE1 of the thin film transistor TFT1.

A second gate metal layer may be disposed on the second gate insulating film 132. The second gate metal layer may include a second capacitor electrode CAE2. The second capacitor electrode CAE2 may overlap the first capacitor electrode CAE1 of the thin film transistor TFT1 in the third direction DR3. Because the second gate insulating film 132 has a known dielectric constant (e.g., a predetermined dielectric constant), the capacitor (e.g., C1 in FIG. 4) may be formed by the first capacitor electrode CAE1, the second capacitor electrode CAE2, and the second gate insulating film 132 disposed between them.

A first interlayer insulating film 141 may be disposed on the second capacitor electrode CAE2.

A first data metal layer may be disposed on the first interlayer insulating film 141. The first data metal layer may include a first source connection electrode PCE1. The first source connection electrode PCE1 may be connected to the first drain area D1 of the first active layer ACT1 through a first source contact hole (e.g., a first source contact opening) PCT1 penetrating (or extending through) the first gate insulating film 131, the second gate insulating film 132, and the interlayer insulating film 141.

A first planarization organic film 160 may be disposed on the first source connection electrode PCE1 to planarize a step caused by the thin film transistor TFT1.

A second data metal layer may be disposed on the first planarization organic film 160. The second data metal layer may include a second source connection electrode PCE2. The second source connection electrode PCE2 may be connected to the first source connection electrode PCE1 through a second source contact hole (e.g., a second source contact opening) PCT2 penetrating (or extending through) the first planarization organic film 160.

A second planarization organic film 180 may be disposed on the second source connection electrode PCE2.

The barrier film BR, the first gate insulating film 131, the second gate insulating film 132, the third gate insulating film 133, and the interlayer insulating film 141 may be formed from an inorganic film, for example, silicon nitride (SiNₓ), silicon oxide (SiON), silicon oxide (SiOₓ), titanium oxide (TiOₓ), or aluminum oxide (AlOₓ).

The first gate metal layer, the second gate metal layer, the first data metal layer, and the second data metal layer may be formed as a single layer or as multiple layers of molybdenum (Mo), aluminum (Al), chromium (Cr), gold (Au), titanium (Ti), nickel (Ni), neodymium (Nd), and copper (Cu), or an alloy thereof.

The first planarization organic film 160 and the second planarization organic film 180 may be formed of an organic film, such as an acrylic resin, an epoxy resin, a phenolic resin, a polyamide resin, a polyimide resin, or the like.

A light emitting element layer may be disposed on the second planarization organic film 180. The light emitting element layer may include pixel electrodes PXE1, PXE2, PXE3, light emitting elements LE, a common electrode CE, and an organic film 190.

A pixel electrode layer including the pixel electrodes PXE1, PXE2, and PXE3 and the common electrode CE may be disposed on a second planarization organic film 180.

Each of the first pixel electrode PXE1, the second pixel electrode PXE2, and the third pixel electrode PXE3 may be connected to the second source connection electrode PCE2 through a connection hole (e.g., a connection opening) (e.g., CT1, CT2, and CT3 in FIG. 5) penetrating (or extending through) the second planarized organic film 180. Each of the pixel electrodes PXE1, PXE2, and PXE3 may be connected to a first source area S1 or a first drain area D1 of the thin film transistor TFT1 through the first source connection electrode PCE1 and the second source connection electrode PCE2. Therefore, a voltage controlled by the thin film transistor TFT1 may be applied to each of the pixel electrodes PXE1, PXE2, and PXE3.

The common electrode CE may be connected to the second power supply line (e.g., VSL in FIG. 4) to which the second driving voltage (e.g., VSS in FIG. 3) is applied through the common connection hole (e.g., CT4 in FIG. 5).

The pixel electrode layer may be formed as a single layer or as multiple layers of molybdenum (Mo), aluminum (Al), chromium (Cr), gold (Au), titanium (Ti), nickel (Ni), neodymium (Nd), and copper (Cu), or alloys thereof. For example, the pixel electrode layer may be made of copper (Cu) with low sheet resistance to lower the resistance of each of the pixel electrodes PXE1, PXE2, and PXE3.

The light emitting element LE may be disposed on each pixel electrode layer. In FIGS. 6 and 7, an embodiment in which the light emitting element LE is a flip-type micro LED is illustrated. The flip-type micro LED refers to an LED in which contact electrodes CTE1 and CTE2 are formed on one side (e.g., the bottom side) of the light emitting element LE.

Each of the plurality of light emitting elements LE may be formed of an inorganic material, such as gallium nitride (GaN).

Each of the plurality of light emitting elements LE may be formed by being grown on a semiconductor substrate, such as a silicon substrate or a sapphire substrate. The plurality of light emitting elements LE may be directly transferred from the semiconductor substrate to the pixel electrode layer of the display panel 100. In another embodiment, the plurality of light emitting elements LE may be transferred onto the pixel electrodes PXE1, PXE2, and PXE3 of the display panel 100 through an electrostatic method by using an electrostatic head or a stamp method by using an elastic polymeric material, such as PDMS or silicone, as a transfer substrate.

The light emitting element LE may include a conductive layer E1, a semiconductor stack STC, a first contact electrode CTE1, a second contact electrode CTE2, and a protective film INS. The semiconductor stack STC may include a first semiconductor layer SEM1, an active layer MQW, a second semiconductor layer SEM2, and a third semiconductor layer SEM3 sequentially arranged in the third direction DR3.

The conductive layer E1 may be disposed on the lower surface of the first semiconductor layer SEM1. Although FIG. 7 illustrates an embodiment in which the conductive layer E1 covers the entire lower surface of the first semiconductor layer SEM1, embodiments of the present disclosure are not limited thereto. In one embodiment, the conductive layer E1 may be disposed on a portion of the lower surface of the first semiconductor layer SEM1. The conductive layer E1 may include any one of molybdenum (Mo), aluminum (Al), chromium (Cr), gold (Au), titanium (Ti), nickel (Ni), neodymium (Nd), and copper (Cu).

The first semiconductor layer SEM1 may be disposed on the conductive layer E1. The first semiconductor layer SEM1 may include a semiconductor material layer doped with a first conductive dopant, such as magnesium (Mg), zinc (Zn), calcium (Ca), strontium (Sr), barium (Ba), or the like, for example, gallium nitride (GaN).

In one embodiment, the first semiconductor layer SEM1 may include a layer of semiconductor material doped with a first conductive dopant, such as magnesium (Mg), zinc (Zn), calcium (Ca), strontium (Sr), barium (Ba), or the like, such as gallium nitride (GaN).

The active layer MQW may be disposed on the first semiconductor layer SEM1. The active layer MQW may emit light by combining electron-hole pairs according to an electrical signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. The well layer may be formed of indium gallium nitride (InGaN), and the barrier layer may be formed of gallium nitride (GaN) or aluminum gallium nitride (AlGaN), but embodiments of the present disclosure are not limited thereto.

In another embodiment, the active layer MQW may have a structure in which semiconductor materials having a high band gap energy and semiconductor materials having a low band gap energy are alternately stacked with each other and may include other Group three to five semiconductor materials according to the wavelength range of emitted light.

For example, when the active layer MQW includes InGaN, the color of the emitted light may vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light emitting element LE that emits the third light (light in the blue wavelength band) may be in a range of approximately 10 wt % to approximately 20 wt %.

The second semiconductor layer SEM2 may be disposed on the first semiconductor layer SEM1. The second semiconductor layer SEM2 may be a semiconductor material layer doped with a second conductivity type dopant, such as silicon (Si), germanium (Ge), tin (Sn), etc., for example, gallium nitride (GaN).

The second semiconductor layer SEM2 may be disposed on the active layer MQW. The second semiconductor layer SEM2 may be a semiconductor material layer doped with a second conductivity type dopant, such as silicon (Si), germanium (Ge), tin (Sn), or the like, for example, gallium nitride (GaN).

The third semiconductor layer SEM3 is a semiconductor material layer in which the n-type dopant is lower than a reference threshold value (e.g., a predetermined threshold value) and may be referred to as an un-doped semiconductor layer. For example, the third semiconductor layer SEM3 may be indium aluminum gallium nitride (InAlGaN), gallium nitride (GaN), aluminum gallium nitride (AlGaN), indium gallium nitride (InGaN), aluminum nitride (AlN), or indium nitride (InN), where the n-type dopant is below a reference threshold. In some embodiments, the third semiconductor layer SEM3 may be omitted.

An electron blocking layer may be disposed between the first semiconductor layer SEM1 and the active layer MQW. The electron blocking layer may be a layer that suppresses or prevents too many electrons from flowing into the active layer MQW. For example, the electron blocking layer may be aluminum gallium nitride (AlGaN) or p-type aluminum gallium nitride (AlGaN) doped with p-type magnesium (Mg). In some embodiments, the electronic blocking layer may be omitted.

A superlattice layer may be disposed between the active layer MQW and the second semiconductor layer SEM2. The superlattice layer may be a layer for relieving stress between the second semiconductor layer SEM2 and the active layer MQW. For example, the superlattice layer may be aluminum gallium nitride (AlGaN) or p-type aluminum gallium nitride (AlGaN) doped with p-type magnesium (Mg). In some embodiments, the superlattice layer may be omitted.

The protective film INS may be a film to protect the bottom and side surfaces of the light emitting element LE. The protective film INS may be disposed on the bottom and side surfaces of the conductive layer E1 and on the side surfaces of the semiconductor stack STC. For example, the protective film INS may be disposed on the bottom and side surfaces of the conductive layer E1, on the side surface of the first semiconductor layer SEM1, on the side surface of the active layer MQW, and on the side surface of the second semiconductor layer SEM2. The protective film INS may be formed of an inorganic film, for example, silicon nitride (SiNₓ), silicon oxide (SiON), silicon oxide (SiOₓ), titanium oxide (TiOₓ), or aluminum oxide (AlOₓ).

A hole (e.g., an opening) LEH exposing the second semiconductor layer SEM2 may be formed through the conductive layer E1, the first semiconductor layer SEM1, and the active layer MQW of the light emitting element LE. The hole LEH may have a circular planar shape, but embodiments of the present disclosure are not limited thereto. For example, the hole LEH may have a polygonal plan shape, such as an elliptical shape or a rectangular shape.

The protective film INS may be disposed on a side of the first semiconductor layer SEM1, on a side of the active layer MQW, and on a side of the second semiconductor layer SEM2. The protective film INS may be a film to protect the side surface of the light emitting element LE. The protective film INS may be formed of an inorganic film, for example, silicon nitride (SiNₓ), silicon oxide (SiON), silicon oxide (SiOₓ), titanium oxide (TiOₓ), or aluminum oxide (AlOₓ).

In addition, the protective film INS may be disposed on the sidewall of the conductive layer E1 exposed in the hole LEH, the sidewall of the first semiconductor layer SEM1, and the sidewall of the active layer MQW. The protective film INS may not cover the second semiconductor layer SEM2 in the hole LEH. Therefore, the second semiconductor layer SEM2 may be exposed without being covered by the protective film INS.

The first contact electrode CTE1 may be disposed on the lower surface of the conductive layer E1. For example, the first contact electrode CTE1 may be disposed on the exposed lower surface of the conductive layer E1 without being covered by the protective film INS. Therefore, the first contact electrode CTE1 may be electrically connected to the conductive layer E1.

The second contact electrode CTE2 may be disposed on the lower surface of the conductive layer E1 and spaced apart from the first contact electrode CTE1. The second contact electrode CTE2 may be disposed on the protective film INS disposed in the hole LEH and on the second semiconductor layer SEM2 exposed in the hole LEH without being covered by the protective film INS. Therefore, the second contact electrode CTE2 may be electrically connected to the second semiconductor layer SEM2 at the hole LEH.

Each of the first contact electrode CTE1 and the second contact electrode CTE2 may include any one of molybdenum (Mo), aluminum (Al), chromium (Cr), gold (Au), titanium (Ti), nickel (Ni), neodymium (Nd), and copper (Cu). For example, each of the first contact electrode CTE1 and the second contact electrode CTE2 may be formed as a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

The plurality of engraved lines AOL may be formed engraved in the second planarization organic film 180. The plurality of engraved lines AOL may extend in the first direction DR1 and may be arranged in the second direction DR2. Each of the plurality of engraved lines AOL may be disposed between the light emitting elements LE and the light emitting elements LE. For example, the engraved line AOL may be disposed between the common electrode CE and the pixel electrodes PX1, PX2, and PX3 of the neighboring sub-pixel. The plurality of engraved lines AOL do not overlap (e.g., are offset from) the pixel electrodes PX1, PX2, and PX3 and the common electrode CE in the thickness direction.

Each of the plurality of engraved lines AOL has a rectangular cross-section and has a width that is wider than the depth. For example, the cross section of each of the plurality of engraved lines AOL may have a depth DL1 in a range of about 0.5 μm to about 2 μm, a width W1 in a range of about 3 μm to about 5 μm, and in one embodiment, a depth DL1 of about 1 μm and a width (W1) of about 4 μm.

As used herein, “in a cross section” and a “cross-section” is defined as viewed in the first direction DR1 or the second direction DR2.

Referring to FIG. 7, each of the plurality of engraved lines AOL is shown as having rectangular in cross section, but the present disclosure is not limited thereto. For example, as shown in FIGS. 9 to 11, the engraved line AOL may have a V-shaped inverted triangle shape, an inverted trapezoid shape, or a semicircle in a cross section. The engraved lines AOL may be formed as having various cross-sections, but the most efficient shape to discharge air when the cross-section is an inverted triangle shape.

A second organic film 211 may be disposed to cover a portion of the side surfaces of the plurality of light emitting elements LE. Further, the second organic film 211 may be disposed to cover the engraved line AOL. Accordingly, the engraved line AOL may be filled with the same material as the second organic film 211. In some embodiments, the second organic film 211 may be disposed to cover the pixel electrodes PXE1, PXE2, and PXE3 and the common electrode CE. The top surface of each of the plurality of light emitting elements LE may be exposed without being covered by the second organic film 211.

The second organic film 211 may be formed from an organic film, such as an acrylic resin, an epoxy resin, a phenolic resin, a polyamide resin, a polyimide resin, or the like.

The second organic film 211 is a layer for flattening the steps caused by the plurality of light emitting elements LE. In FIGS. 6 and 7, the second organic film 211 is shown as a single layer, but it is not limited thereto. For example, the second organic film 211 may be formed by stacking a plurality of organic films.

A first capping layer CAP1 may be disposed on the common electrode CE.

A light blocking layer BM, a first light conversion layer QDL1, a second light conversion layer QDL2, and a light transmission layer TPL may be disposed on the first capping layer CAP1. The first light conversion layer QDL1, the second light conversion layer QDL2, and the light transmission layer TPL may be formed by the compartments the light blocking layer BM. Therefore, the first light conversion layer QDL1 may be disposed on the first capping layer CAP1 in the first sub-pixel SPX1, the second light conversion layer QDL2 may be disposed on the first capping layer CAP1 in the second sub-pixel SPX2, and the light transmission layer TPL may be disposed on the first capping layer CAP1 in the third sub-pixel SPX3. The light blocking layer BM may not overlap (e.g., may be offset from) the plurality of light emitting elements LE in the third direction DR3.

The first light conversion layer QDL1 may convert a portion of the third light (light in the blue wavelength band) incident from the light emitting element LE into first light (light in the red wavelength band). The first light conversion layer QDL1 may include a first base resin BRS1 and a first wavelength conversion particle WCP1. The first base resin BRS1 may include a light-transmitting organic material. The first wavelength conversion particle WCP1 may convert a portion of the third light (light in the blue wavelength band) incident from the light emitting element LE into first light (light in the red wavelength band).

The second light conversion layer QDL2 may convert a portion of the third light (light in the blue wavelength band) incident from the light emitting element LE into second light (light in the green wavelength band). The second light conversion layer QDL2 may include a second base resin BRS2 and a second wavelength conversion particle WCP2. The second base resin BRS2 may include a light-transmitting organic material. The second wavelength conversion particle WCP2 may convert a portion of the third light (light in the blue wavelength band) incident from the light emitting element LE into second light (light in the green wavelength band).

The light transmission layer TPL may include a light-transmitting organic material.

For example, the first base resin BRS1, the second base resin BRS2, and the light transmission layer TPL may include an epoxy-based resin, an acrylic-based resin, a cado-based resin, or an imide-based resin. The first and second wavelength conversion particles WCP1 and WCP2 may be quantum dots (QD), quantum rods, fluorescent materials, or phosphorescent materials.

The light blocking layer BM may include a first light blocking layer BM1 and a second light blocking layer BM2 that are sequentially stacked. A length of the first light blocking layer BM1 in the first direction DR1 or a length in the second direction DR2 may be wider than a length of the second light blocking layer BM2 in the first direction DR1 or a length in the second direction DR2. The first light blocking layer BM1 and the second light blocking layer BM2 may be formed of an organic film, such as an acrylic resin, an epoxy resin, a phenolic resin, a polyamide resin, a polyimide resin, or the like. The first light blocking layer BM1 and the second light blocking layer BM2 may include a light blocking material to prevent light from the light emitting element LE of one sub-pixel from proceeding to the neighboring sub-pixel. For example, the first light blocking layer BM1 and the second light blocking layer BM2 may include an inorganic black pigment, such as carbon black or an organic black pigment.

The second capping layer CAP2 may be disposed on the first capping layer CAP1 and the light blocking layer BM. The second capping layer CAP2 may be disposed on the side and top surfaces of the light blocking layer BM. For example, the second capping layer CAP2 may be disposed on the side of the first light blocking layer BM1 and the side and top surfaces of the second light blocking layer BM2.

The reflective film RF may be disposed between the light blocking layer BM and the first light conversion layer QDL1, between the light blocking layer BM and the second light conversion layer QDL2, and between the light blocking layer BM and the light transmission layer TPL. The reflective film RF may be disposed on a second capping layer CAP2 disposed on the side of the first light blocking layer BM1 and the side of the second light blocking layer BM2. The reflective film RF reflects light traveling in the lateral direction from the first light conversion layer QDL1, the second light conversion layer QDL2, and the light transmission layer TPL.

The reflective film RF may include a highly reflective metal material such as aluminum (Al). The thickness of the reflective film RF may be approximately 0.1 μm.

In another embodiment, the reflective layer RF2 may include a first layer and a second layer of M (M being an integer of 2 or more) pairs having different refractive indices to act as Distributed Bragg Reflectors (DBR). In such an embodiment, M first layers and M second layers may be alternately arranged. The first layer and the second layer may be formed of an inorganic film, for example, silicon nitride (SiNₓ), silicon oxide (SiON), silicon oxide (SiOₓ), titanium oxide (TiOₓ), or aluminum oxide (AlOₓ).

The third capping layer CAP3 may be disposed on the second capping layer CAP2, the first light conversion layer QDL1, the second light conversion layer QDL2, and the light transmission layer TPL.

The first capping layer CAP1, the second capping layer CAP2, and the third capping layer CAP3 may be formed of an inorganic film, for example, silicon nitride (SiNₓ), silicon oxide (SiON), silicon oxide (SiOₓ), titanium oxide (TiOₓ), or aluminum oxide (AlOₓ). The first light conversion layer QDL1, the second capping layer CAP2, and the third capping layer CAP3 may be encapsulated by the first capture layer CAP1, the second capping layer CAP2, and the third capping layer CAP3.

A fourth organic film 213 may be disposed on the second capping layer CAP2. A plurality of color filters CF1, CF2, and CF3 may be disposed on the fourth organic film 213. The plurality of color filters CF1, CF2, and CF3 may include first color filters CF1, second color filters CF2, and third color filters CF3.

The first color filter CF1 disposed in the first sub-pixel SPX1 may transmit the first light (light in the red wavelength band) and may absorb or block the third light (light in the blue wavelength band). Therefore, the first color filter CF1 may transmit the first light (light in the red wavelength band) that has been converted by the first light conversion layer QDL1 from among the third light (light in the blue wavelength band) emitted from the light emitting element LE and may absorb or block the third light (light in the blue wavelength band) that has not been converted by the first light conversion layer QDL1. Accordingly, the first sub-pixel SPX1 may emit the first light (light in the red wavelength band).

The second color filter CF2 disposed in the second sub-pixel SPX2 may transmit the second light (light in the green wavelength band) and may absorb or block the third light (light in the blue wavelength band). Therefore, the second color filter CF2 may transmit the second light (light in the green wavelength band) that has been converted by the first light conversion layer QDL1 from among the third light (light in the blue wavelength band) emitted from the light emitting element LE and may absorb or block the third light (light in the blue wavelength band) that has not been converted by the first light conversion layer QDL1. Accordingly, the second sub-pixel SPX2 may emit the second light (light in the green wavelength band).

The third color filter CF3 disposed in the third sub-pixel SPX3 may transmit the third light (light in the blue wavelength band). Therefore, the third color filter CF3 may transmit the third light (light in the blue wavelength band) emitted from the light emitting element LE passing through the light transmission layer TPL. Accordingly, the third sub-pixel SPX3 may emit the third light (light in the blue wavelength band).

The first color filter CF1, the second color filter CF2, and the third color filter CF3 may partially overlap in the third direction DR3 and may overlap with the light blocking layer BM in the third direction DR3.

A fifth organic film 214 may be disposed on the plurality of color filters CF1, CF2, and CF3 for planarization.

The fourth organic film 213 and the fifth organic film 214 may be formed from an acrylic resin, an epoxy resin, a phenolic resin, a polyamide resin, a polyimide resin, or the like.

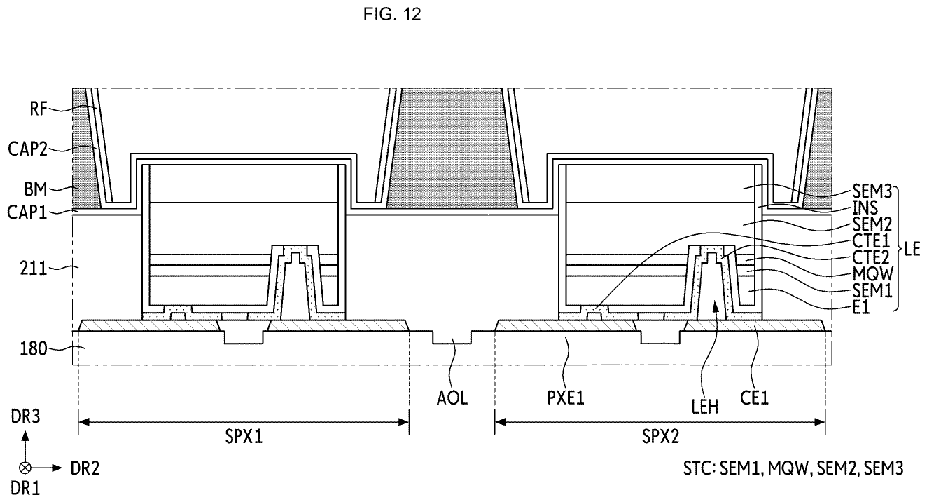

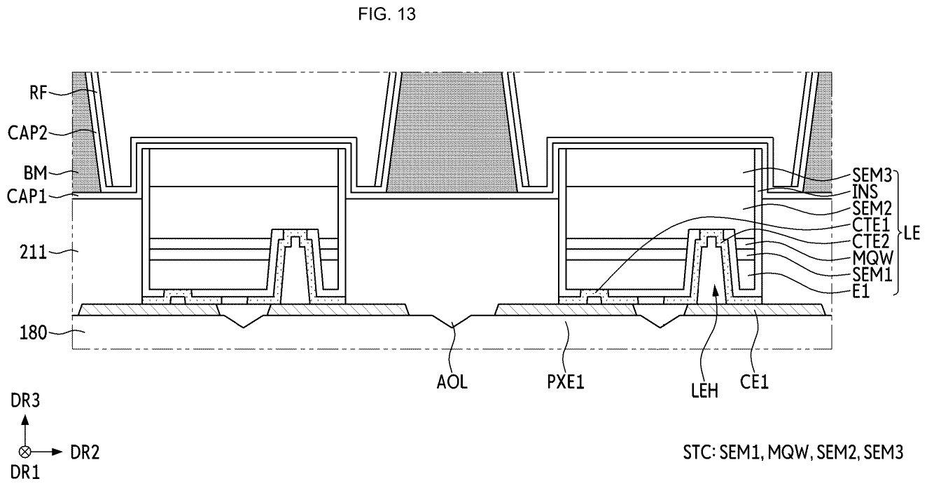

FIGS. 12 and 13 are cross-sectional views of the area A in FIG. 6 according to other embodiments.

The embodiment shown in FIG. 12 is different from the embodiment shown in FIG. 7 in that the engraved line AOL is further disposed between the pixel electrodes PXE1 and PXE2 and the common electrode CE to overlap the light emitting element LE. In FIG. 12, descriptions that are the same as or substantially similar as those with reference to the embodiment shown in FIG. 7 may be omitted or only briefly repeated, and the description of the embodiment shown in FIG. 12 will focus on differences from the embodiment shown in FIG. 7.

Referring to FIG. 12, a plurality of engraved lines AOL may be formed in the second planarization organic film 180. The plurality of engraved lines AOL may be disposed between the common electrode CE and the pixel electrodes PX1 and PX2. The plurality of engraved lines AOL do not overlap (e.g., are offset from) the pixel electrodes PX1 and PX2 and the common electrode CE in the thickness direction. For example, the plurality of engraved lines AOL may be disposed between the sub-pixels SPX1 and SPX2, as well as the pixel electrodes PX1 and PX2 and the common electrode CE within each sub-pixel SPX1 and SPX2.

Each of the plurality of engraved lines AOL has a rectangular cross-section and has a width greater than a depth. For example, the cross-section of each of the plurality of engraved lines AOL may have a depth DL1 in a range of about 0.5 μm to about 2 μm and a width W1 in a range of about 3 μm to about 5 μm, and in one embodiment, a depth DL1 of about 1 μm and a width W1 of about 4 μm.

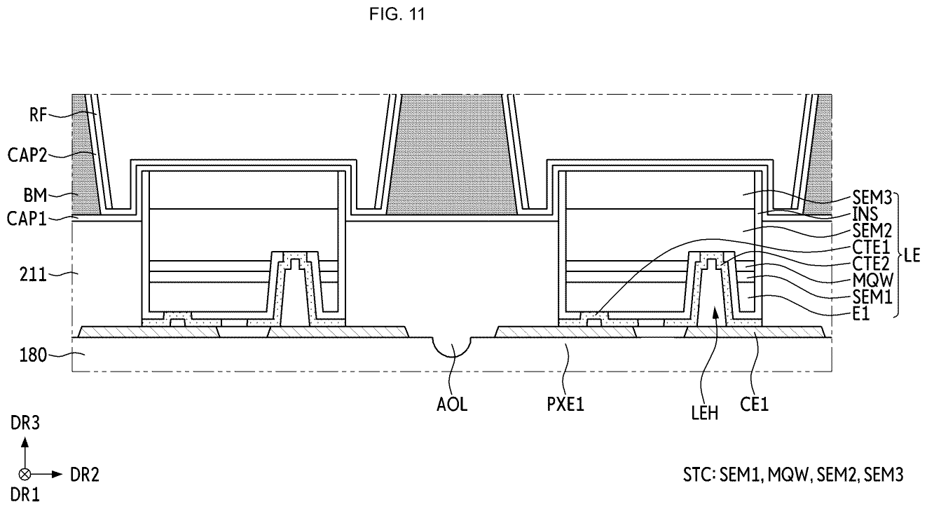

Referring to FIG. 12, each of the plurality of engraved lines AOL is illustrated as having a rectangular cross-section, but the present disclosure is not limited thereto. For example, as shown in FIG. 11, the engraved line AOL may be V-shaped and may have an inverted triangle cross-sectional shape. In another embodiment, each of the plurality of engraved lines AOL may have various polygonal shapes, such as an inverted trapezoid or trapezoidal cross-sectional shape or may have a semicircular shape.

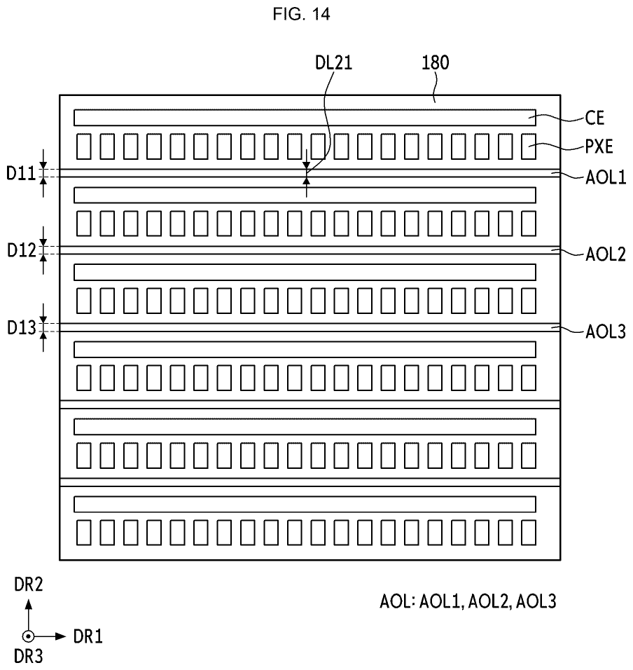

FIGS. 14 to 16 are layouts of a plurality of engraved lines according to one embodiment.

FIGS. 14 to 16 illustrate a plurality of engraved lines on the second planarization organic film 180 in a plan view. As used herein, “in a plan” is set based on a plane parallel to the plane defined by the first direction DR1 and the second direction DR2.

Each of the plurality of engraved lines AOL may extend in the first direction DR1 and may be arranged in the second direction DR2. For example, each of the plurality of engraved lines AOL may have a constant depth and may extend uninterruptedly (e.g., continuously) from one end to the other end in the first direction DR1 of the second planarization organic film 180. The common electrode CE, the pixel electrode PXE, and the engraved line AOL may be sequentially arranged in the second direction DR2 of the second planarization organic film 180 in that order.

As shown in FIG. 14, each of the plurality of engraved lines AOL may have the same shape. For example, a width DL11 of the first engraved line AOL1, a width DL12 of the second engraved line AOL2, and a width DL13 of the third engraved line AOL3 may be the same as each other.

Additionally, each of the plurality of engraved lines AOL may have the same width from one end to the other end in the first direction DR1. For example, a width D21 at the center of the first engraved line AOL1 may be the same as a width D11 at one end of the first engraved line AOL1.

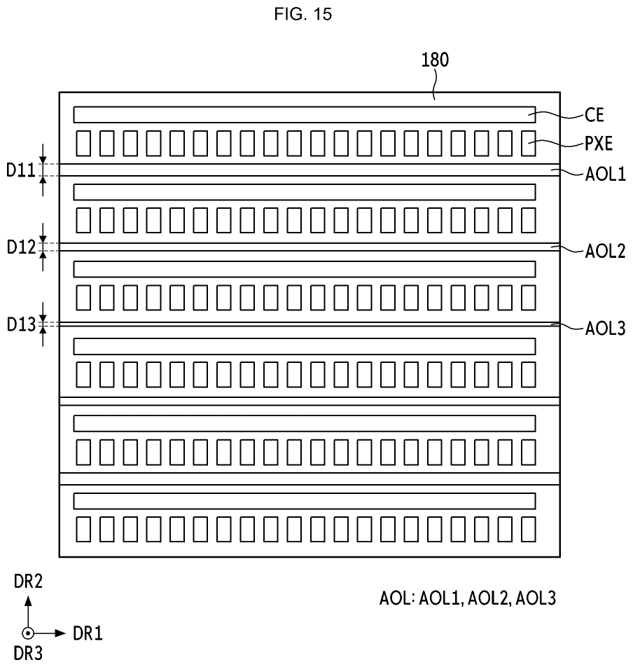

As shown in FIG. 15, from among the plurality of engraved lines AOL, the width of the engraved line may be wider as the engraved line is disposed on the outer side from the center. For example, the first engraved line AOL1, the second engraved line AOL2, and the third engraved line AOL3 may be sequentially disposed from the outer edge to the center in that order. According to the arrangement order from the outermost toward the center, the width DL11 of the first engraved line AOL1 may be wider than the width DL12 of the second engraved line AOL2, and the width DL12 of the second engraved line AOL2 may be wider than the width DL13 of the first engraved line AOL1. That is, the width D11 of the first engraved line AOL1 disposed at the outermost side is wider than the width D13 of the third engraved line AOL3 disposed in the center.

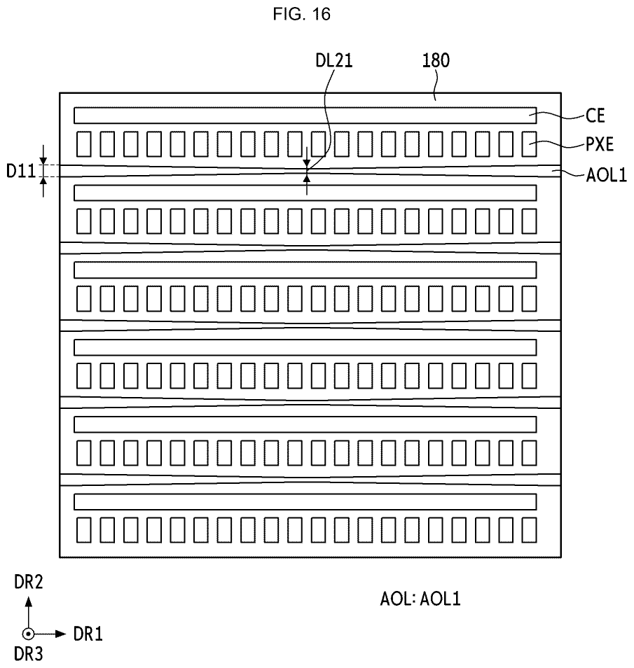

As shown in FIG. 16, each of the plurality of engraved lines AOL may become wider from the center toward one end of each line. The width at one end DL11 of the first engraved line AOL may be wider than the width DL21 at the center.

In one embodiment, by making the engraved line wider from the center toward one end, air in the bubble layer, which is more likely to be generated in the center, may be more easily discharged to the outside.

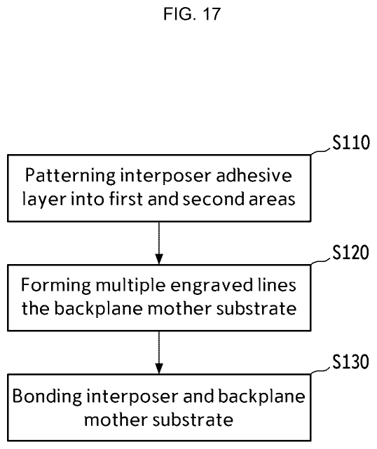

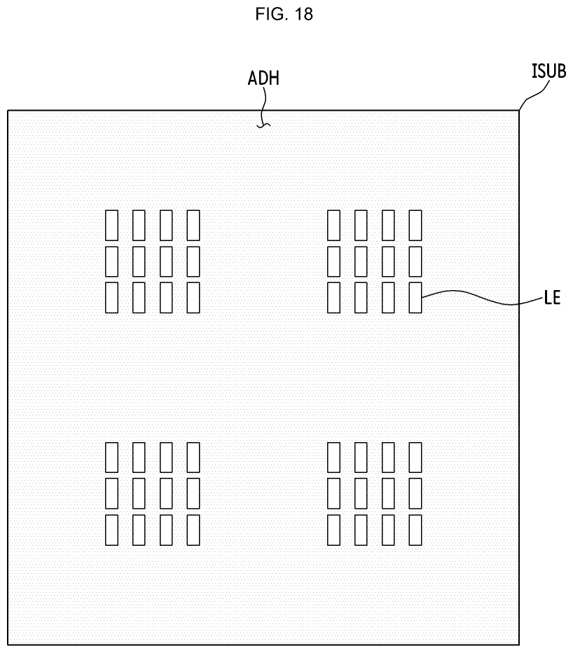

FIG. 17 is a flowchart describing steps of a method of manufacturing a display device according to one embodiment. FIGS. 18 to 22 are schematic diagrams illustrating steps of a method of manufacturing a display device according to one embodiment.

Hereinafter, a method of manufacturing a display device according to one embodiment will be described, in detail, with reference to FIGS. 17 to 22.

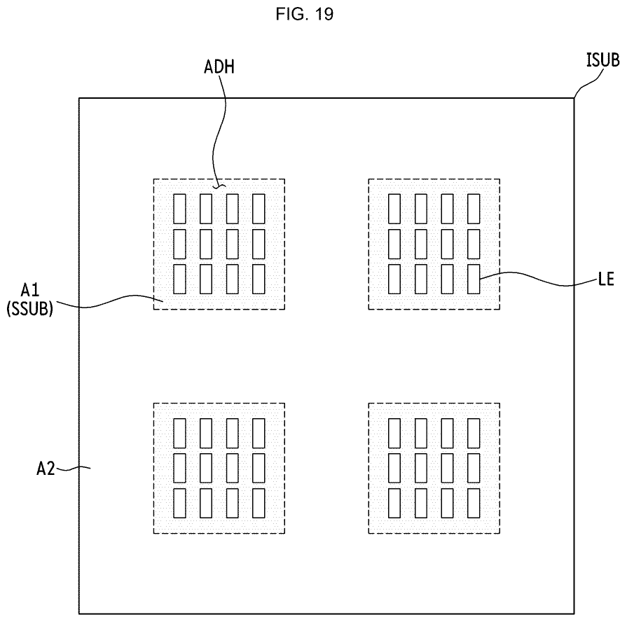

First, as shown in FIGS. 18 and 19, an adhesive layer ADH of an interposer ISUB is patterned into a first area A1 and a second area A2 (S110 in FIG. 17)

The interposer ISUB may be a large relay board including a plurality of sub-interposers SSUB. Each sub-interposer SSUB may have a size and/or shape corresponding to a cell of the backplane mother substrate. The sub-interposers SSUB may be disposed in the interposer ISUB to match a plurality of cells of the backplane mother substrate.

The backplane mother substrate is a substrate used to concurrently (or simultaneously) manufacture a plurality of display panels 100 and includes a plurality of cell areas to be divided into the backplane substrate of each of a plurality of display panels 100. In one embodiment, the backplane mother substrate may have an area including about 1,120 1.2-inch cells, but the area is not limited thereto.

The interposer ISUB may be made of a rigid material, such as plastic, organic glass, optical glass, ceramic, or the like.

In one embodiment, the adhesive layer ADH may be provided and/or formed on one surface of the interposer ISUB. The adhesive layer ADH may be used to transfer the light emitting elements LE to the backplane mother substrate in a subsequent process.

In one embodiment, the adhesive layer ADH may be formed of a material suitable for a process method to be applied when transferring the light emitting element LE onto the backplane mother substrate. For example, if the light emitting elements LE are to be separated from the interposer ISUB by using a laser lift off (LLO) method, the adhesive layer ADH may be formed from a material that facilitates separation of the light emitting elements LE from the interposer ISUB by the LLO method. For example, if the adhesive layer ADH is formed with a material that is sensitive to a laser, such as a thermoplastic adhesive, a pyrolyzable adhesive, or an incompletely cured adhesive, which may weaken the adhesion, the light emitting elements LE and the interposer ISUB may be easily separated by the LLO method. The separation method of the light emitting elements LE and the interposer ISUB is not limited to the LLO method, and the adhesive layer ADH may be formed from a material suitable for the selected separation method.

In some embodiments, the adhesive layer ADH is first applied to the entire surface of the interposer ISUB to a first thickness. The first thickness may be about 50 μm to 60 μm but is not limited thereto. Thereafter, the adhesive layer ADH on the interposer ISUB is patterned into a first area A1 corresponding to the sub-interposer SSUB and a second area A2 that is the other area.

For example, the second area A2 may be patterned by removing, thinning, or reducing the adhesive component of the adhesive layer.

By patterning the adhesive in the second area A2 by removing, thinning, or reducing the adhesive component, it not only facilitates the separation of the interposer ISUB during the bonding process but also reduces or minimizes the formation of a bubble layer between the interposer ISUB and the backplane mother substrate BP and allows air to be easily discharged from the bubble layer.

The light emitting element LE may be disposed on the adhesive layer ADH of the sub-interposer SSUB for which patterning has been completed.

As in one embodiment, by removing or reducing the adhesive strength of the adhesive in the second area A2 other than the sub-interposer SSUB after bonding the interposer ISUB and the backplane mother substrate the interposer ISUB may be easily removed from the backplane mother substrate.

Each of the plurality of light emitting elements LE may be formed by being grown on a semiconductor substrate, such as a silicon substrate or sapphire substrate. The plurality of light emitting elements LE may be transferred from a semiconductor substrate to an interposer ISUB through a relay substrate. In another embodiment, the plurality of light emitting elements LE may be transferred to the relay substrate through an electrostatic method by using an electrostatic head or a stamp method by using an elastic polymer material, such as PDMS or silicon as a transfer substrate, and then transferred to the interposer ISUB.

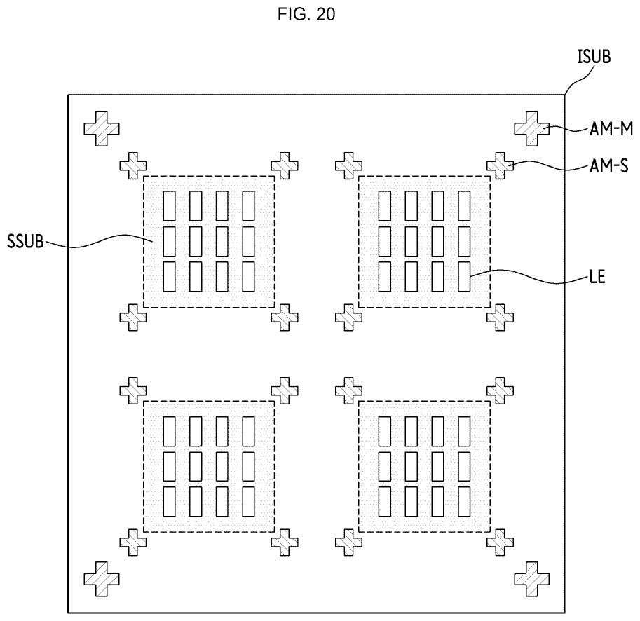

Referring to FIG. 20, a plurality of alignment marks AM are formed on the interposer ISUB. The plurality of alignment marks AM may include a main alignment mark AM-M for cementation and a sub-alignment mark AM-S for transfer.

An alignment mark may be printed by performing screen printing by using a mask in the area where the alignment mark is to be formed.

The main alignment mark AM-M may be placed adjacent to a vertex within the interposer ISUB and at a position that does not overlap with (e.g., that is offset from) the sub-interposer ISUB.

The sub-alignment mark AM-S may be placed adjacent to the vertex of the sub-interposer ISUB outside the sub-interposer ISUB. Accordingly, the number of sub-alignment marks AM-S may be greater than the number of main alignment marks AM-M. The number of sub-alignment marks AM-S may correspond to the number of vertices of the polygon defining the sub-interposer ISUB but is not limited thereto.

The main alignment mark AM-M may be placed outside the sub-alignment mark AM-S. The main alignment mark AM-M and the sub-alignment mark AM-S may have the same area or different areas. The shape and number of the main alignment mark AM-M and sub-alignment mark AM-S are not limited. For example, as shown in FIG. 18, the main alignment mark AM-M and the sub-alignment mark AM-S may be cross-shaped.

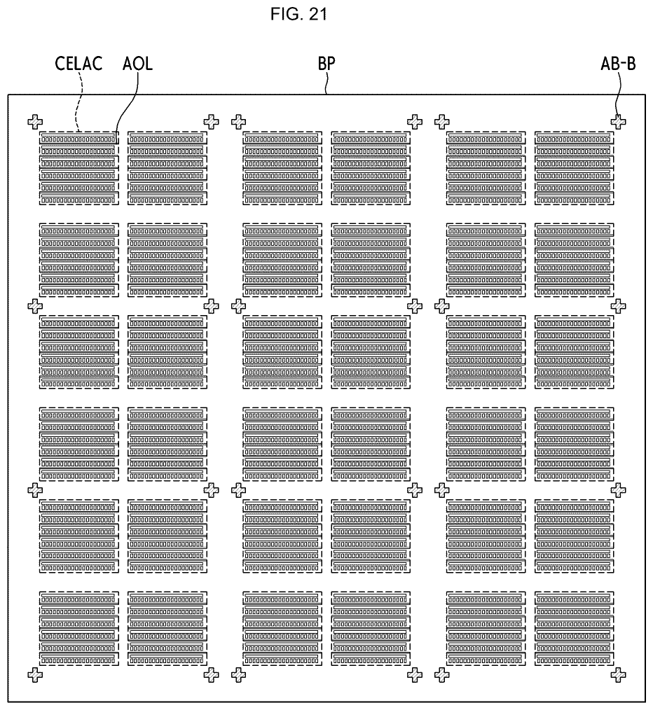

As shown in FIG. 21, a plurality of engraved lines AOL are formed on the backplane mother substrate BP (S120 in FIG. 17).

The plurality of engraved lines AOL are formed in the cell areas CELA of the backplane mother substrate BP. The shapes and positions of the plurality of engraved lines AOL correspond to the engraved lines AOL described above with reference to FIGS. 5 to 16.

The plurality of engraved lines AOL may be formed by using a half tone mask in which areas with different transmittances exist within a single mask. By controlling the transmittance of the halftone, the depth of the engraved line AOL may be easily controlled.

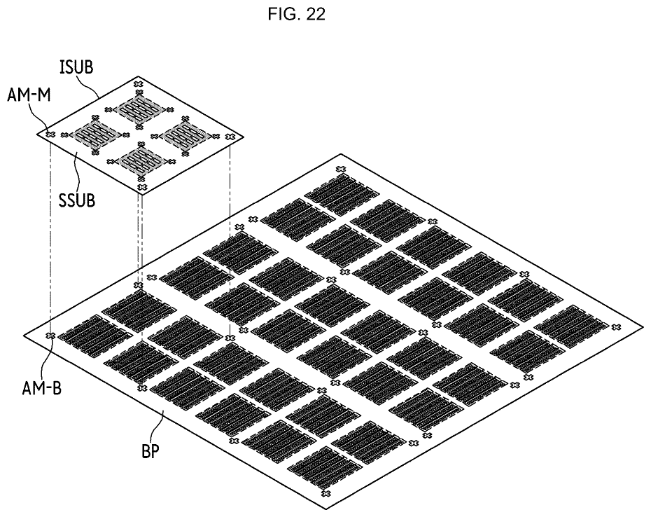

As shown in FIG. 22, the light emitting element LE is transferred by bonding the interposer ISUB and the backplane mother substrate BP (S130 in FIG. 17)

The light emitting element LE disposed on the interposer ISUB is arranged to face the backplane mother substrate BP, and the main alignment mark AM-M of the interposer ISUB and the lower alignment mark AM-B on the backplane mother substrate BP. When the main alignment mark AM-M of the interposer ISUB and the lower alignment mark AM-B of the backplane mother substrate BP are aligned, the interposer ISUB is bonded to the backplane mother substrate BP. A bubble layer may occur when bonding the interposer ISUB and backplane mother substrate BP. The air in the generated bubble layer may be discharged along the engraved line AOL. Therefore, the engraved line AOL may be referred to as the air discharge line.

Thereafter, by checking the sub-alignment mark AM-S of the interposer ISUB, the light emitting element LE is bonded to the pixel electrode and the common electrode of the backplane mother substrate BP, and the interposer ISUB is peeled off from the light emitting element LE. Accordingly, the transfer process of the light emitting element LE may be completed.

The backplane mother substrate BP may be divided into individual cells. Each backplane mother substrate BP divided into each sensor unit may become a display panel 100.

Thereafter, as shown in FIG. 7, a second organic film, a light blocking layer, a wavelength conversion layer, a light transmission layer, and a color filter layer are sequentially formed.

A second organic film 211 may be formed on the second planarization organic film 180 to flatten the steps caused by the light emitting elements LE. A material for forming the second organic film 211 may be filled in the engraved line AOL.

A first capping layer CPL1 is formed on the second organic film 211 and the light emitting elements LE, and a first light blocking layer BM1 and a second light blocking layer BM2 are formed on the first capping layer CPL1, which overlaps with the light emitting elements LE in the third direction DR3. Then, a second capping layer CPL2 is formed to cover the first light blocking layer BM1, the second light blocking layer BM2, and the first capping layer CPL1. Then, a reflective film RF is formed to cover the second capping layer CPL2 disposed on the first light blocking layer BM1 and the second light blocking layer BM2.

Then, a first light conversion layer QDL1 is formed in each of the first sub-pixels SPX1, a second light conversion layer QDL2 is formed in each of the second sub-pixels SPX2, and a light transmission layer TPL is formed on each of the third sub-pixels SPX3. Then, a third capping layer CPL3 is formed to cover the first light conversion layers QDL1, the second light conversion layers QDL2, and the light transmission layer TPL. Then, the fourth organic film 213 is formed on the third capping layer CPL3.

Then, a first color filter CF1 is formed on the fourth organic film 213 to overlap the first light conversion layers QDL1 in the third direction DR3, a second color filter CF2 is formed to overlap the second light conversion layers QDL2 in the third direction DR3, and a third color filter CF3 is formed to overlap the light transmission layers TPL in the third direction DR3. The first color filter CF1, the second color filter CF2, and the third color filter CF3 may all be formed in (e.g., may each be present in) the area overlapping the first light blocking layer BM1 and the second light blocking layer BM2 in the third direction DR3.

Then, a fifth organic film 214 is formed on the first color filter CF1, the second color filter CF2, and the third color filter CF3.

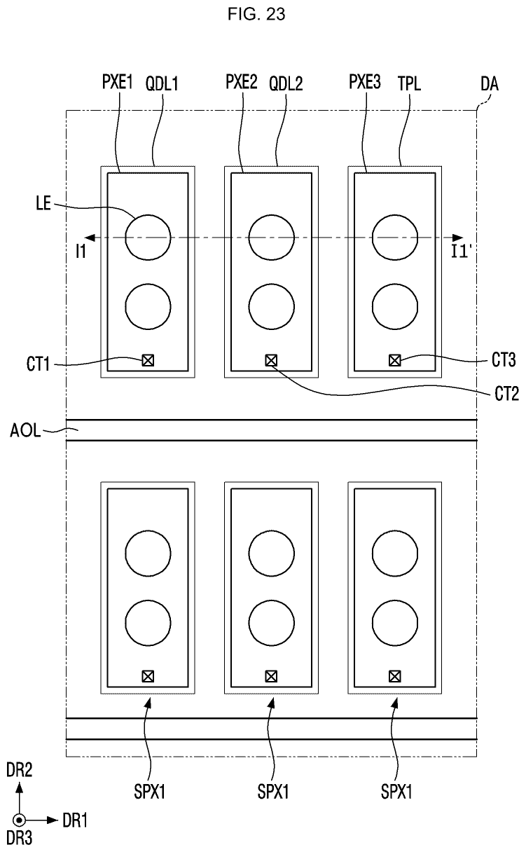

FIG. 23 is a layout diagram illustrating pixels of a display area according to another embodiment.

The embodiment shown in FIG. 23 differs from the embodiment shown in FIG. 5 in that the light emitting element LE in each of the first sub-pixel SPX1, the second sub-pixel SPX2, and the third sub-pixel SPX3 has a common electrode CE1 disposed on the light emitting element LE. In the embodiment shown in FIG. 23, descriptions that are the same as or substantially similar to those with respect to the embodiment shown in FIG. 5 may be omitted or only briefly provided.

Referring to FIG. 23, the first sub-pixel SPX1 includes a first pixel electrode PXE1, a plurality of light emitting elements LE, and a first light conversion layer QDL1. The second sub-pixel SPX2 includes a second pixel electrode PXE2, a plurality of light emitting elements LE, and a second light conversion layer QDL2. The third sub-pixel SPX3 includes a third pixel electrode PXE3, a plurality of light emitting elements LE, and a third light conversion layer QDL3.

Each of the first pixel electrode PXE1, the second pixel electrode PXE2, and the third pixel electrode PXE3 may have a rectangular planar shape with a short side in the first direction DR1 and a long side in the second direction DR2.

Each of the pixel electrodes PXE1, PXE2, and PXE3 may be electrically connected to at least one transistor through the pixel connection hole (e.g., the pixel connection opening) CT1, CT2, and CT3. For example, each of the pixel electrodes PXE1, PXE2, and PXE3 may be electrically connected to the second electrode of the fourth transistor (e.g., ST4 in FIG. 4) and the second electrode of the sixth transistor (e.g., ST6 in FIG. 4) of the corresponding sub-pixel.

A plurality of light emitting elements LE may be disposed on each of the pixel electrodes PXE1, PXE2, and PXE3. The same number of light emitting elements LE may be disposed on each of the pixel electrodes PXE1, PXE2, and PXE3. For example, two light emitting elements LE may be disposed on each of the pixel electrodes PXE1, PXE2, and PXE3. The plurality of light emitting elements LE may emit light of a third color, that is, light in a blue wavelength band, but embodiments of the present disclosure are not limited thereto.

Each of the plurality of light emitting elements LE may have a circular planar shape, but embodiments of the present disclosure are not limited thereto. For example, each of the plurality of light emitting elements LE may have a rectangular planar shape.

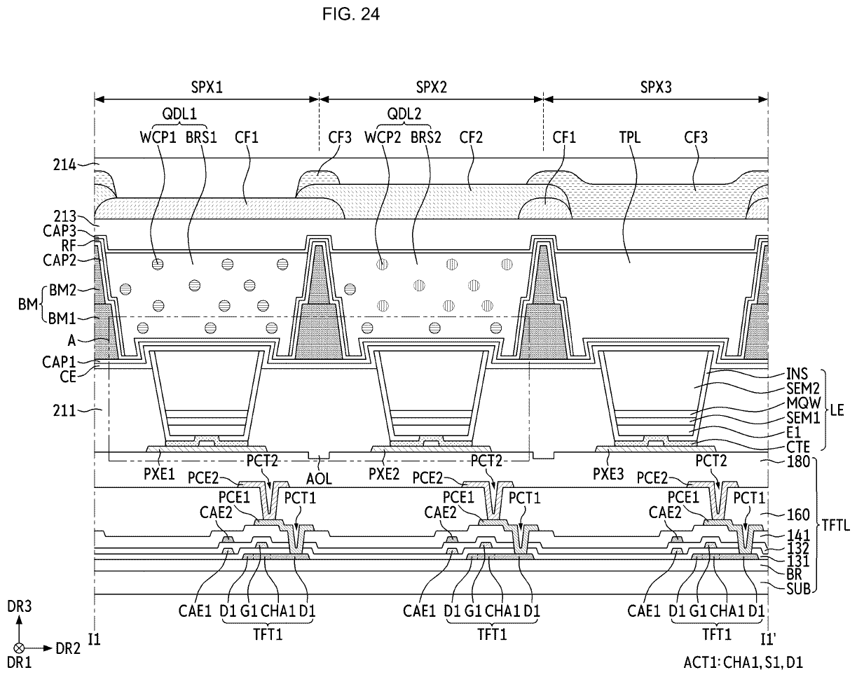

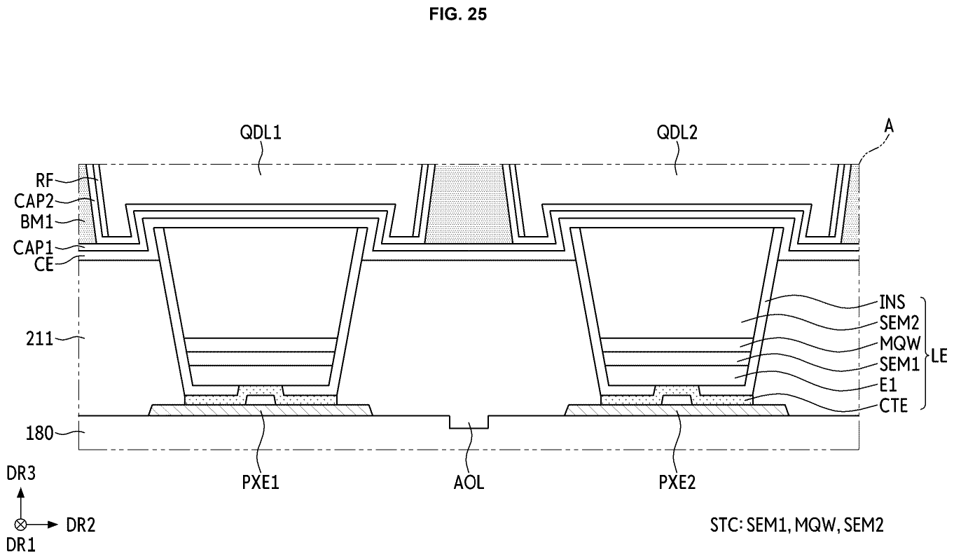

FIG. 24 is a cross-sectional view of a display panel taken along the to lines II-II′ in FIG. 23. FIG. 25 is a cross-sectional view of the area A in FIG. 23 in detail.

The embodiment shown in FIGS. 24 and 25 are different from the embodiment shown in FIGS. 6 and 7 in that the light emitting element LE is a vertical micro LED. In FIGS. 24 and 25, descriptions that are the same as or substantially similar to those with respect to the embodiment shown in FIGS. 6 and 7 may be omitted or only briefly provided, and the description will focus on differences from the embodiment shown in FIGS. 6 and 7.

Referring to FIGS. 24 and 25, the pixel electrodes PXE1, PXE2, and PXE3 may be disposed on the second planarization organic film 180.

A plurality of light emitting elements LE may be disposed on the pixel electrodes PXE1, PXE2, and PXE3. Each of the plurality of light emitting elements LE may be a vertical type micro LED extending in the third direction DR3. A vertical micro LED refers to an LED having a structure in which a first semiconductor layer SEM1, an active layer MQW, and a second semiconductor layer SEM2 are sequentially arranged in the vertical third direction DR3.

Each of the plurality of light emitting elements LE may have an inverse tapered cross-sectional shape. For example, each of the plurality of light emitting elements LE may have a trapezoidal cross-sectional shape in which the width of the top surface is wider than the width of the bottom surface, but the present disclosure is not limited thereto, and each of the plurality of light emitting elements LE may have a rectangular cross-sectional shape where the top and bottom surfaces have the same width. Each of the plurality of light emitting elements LE may be formed of an inorganic material, such as gallium nitride (GaN). Each of the plurality of light emitting elements LE may have a length of several to hundreds of μm in the first direction DR1, a length in the second direction DR2, and a length in the third direction DR3. For example, each of the plurality of light emitting elements LE may have a length in the first direction DR1, a length in the second direction DR2, and a length in the third direction DR3 of approximately 100 μm or less.

The light emitting element LE may include a conductive layer E1, a semiconductor stack STC, a contact electrode CTE, and a protective film INS. The semiconductor stack STC may include the first semiconductor layer SEM1, the active layer MQW, the second semiconductor layer SEM2, and the third semiconductor layer SEM3 sequentially disposed in the third direction DR3.

The protective film INS may be a film to protect the bottom and side surfaces of the light emitting element LE. The protective film INS may be disposed on the bottom and side surfaces of the conductive layer E1 and the side surfaces of the semiconductor stack STC. The contact electrode CTE may be disposed on the protective film INS. Each of the contact electrodes CTE may be connected to the exposed conductive layer E1 that is not covered by the protective film INS.

A plurality of engraved lines AOL may be formed in the second planarization organic film 180. The plurality of engraved lines AOL may extend in the first direction DR1 and may be arranged in the second direction DR2. Each of the plurality of engraved lines AOL may be disposed between the light emitting elements LE and the light emitting elements LE. For example, they may be disposed between the pixel electrodes PX1, PX2, and PX3 of the sub-pixel.

The second organic film 211 may be disposed to cover a portion of the side surfaces of the plurality of light emitting elements LE.

The common electrode CE may be disposed on the top surface of each of the plurality of light emitting elements LE and the top surface of the second organic film 211. The common electrode CE may be a common layer commonly formed in the first sub-pixel SPX1, the second sub-pixel SPX2, and the third sub-pixel SPX3. The common electrode CE may be made of a transparent conductive material (TCO), such as indium tin oxide (ITO) and indium zinc oxide (IZO), that may transmit light. The pixel electrodes PXE1, PXE2, and PXE3 may be referred to as an anode electrode or a first electrode, and the common electrode CE may be referred to as a cathode electrode or a second electrode.

The first capping layer CAP1 may be disposed on the common electrode CE.

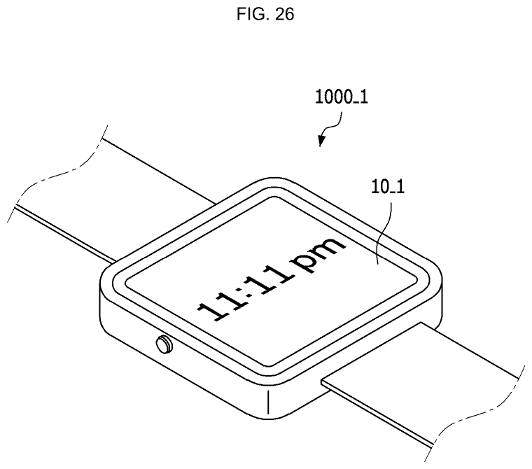

FIG. 26 illustrates a smart watch including a display device according to an embodiment.

Referring to FIG. 26, a display device 10_1, according to an embodiment, may be applied to a smart watch 1000_1, which is one of smart devices.

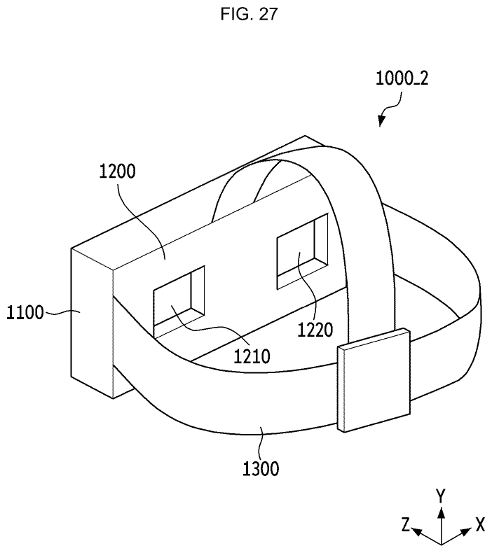

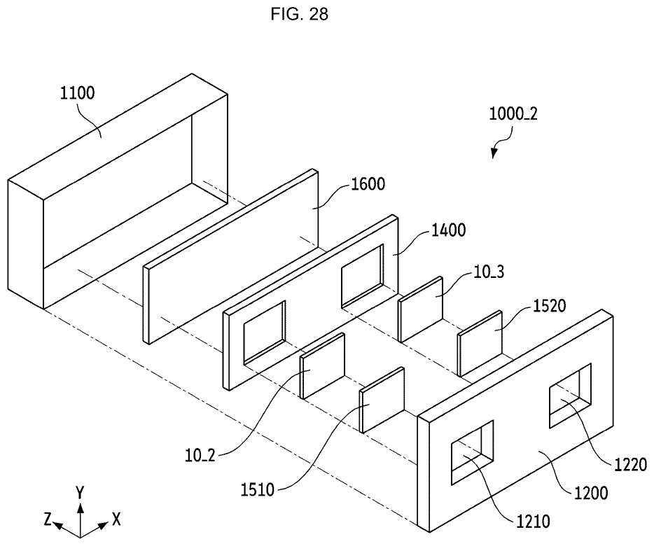

FIGS. 27 and 28 are views of a virtual reality (VR) device including a display device according to an embodiment.

Referring to FIGS. 27 and 28, a head mounted display device 1000_2, according to an embodiment, includes a first display device 10_2, a second display device 10_3, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_2 provides an image to a user's left eye, and the second display device 10_3 provides an image to the user's right eye. Each of the first display device 10_2 and the second display device 10_3 may be substantially the same as the display device 10 described with reference to FIGS. 1 and 2. Therefore, a description of the first display device 10_2 and the second display device 10_3 will be omitted.

The first optical member 1510 may be disposed between the first display device 10_2 and the first eyepiece 1210. The second optical member 1520 may be disposed between the second display device 10_3 and the second eyepiece 1220. Each of the first optical member 1510 and the second optical member 1520 may include at least one convex lens.

The middle frame 1400 may be disposed between the first display device 10_2 and the control circuit board 1600 and may be disposed between the second display device 10_3 and the control circuit board 1600. The middle frame 1400 supports and fixes the first display device 10_2, the second display device 10_3, and the control circuit board 1600.

The control circuit board 1600 may be disposed between the middle frame 1400 and the display device housing 1100. The control circuit board 1600 may be connected to the first display device 10_2 and the second display device 10_3 through a connector. The control circuit board 1600 may convert an image source received from the outside into digital video data DATA and transmit the digital video data DATA to the first display device 10_2 and the second display device 10_3 through the connector.

The control circuit board 1600 may transmit the digital video data DATA corresponding to a left image optimized for a user's left eye to the first display device 10_2 and transmit the digital video data DATA corresponding to a right image optimized for the user's right eye to the second display device 10_3. In another embodiment, the control circuit board 1600 may transmit the same digital video data DATA to the first display device 10_2 and the second display device 10_3.

The display device housing 1100 houses the first display device 10_2, the second display device 10_3, the middle frame 1400, the first optical member 1510, the second optical member 1520, and the control circuit board 1600. The housing cover 1200 is arranged to cover an open surface of the display device housing 1100. The housing cover 1200 may include the first eyepiece 1210 on which a user's left eye is placed and the second eyepiece 1220 on which the user's right eye is placed. Although the first eyepiece 1210 and the second eyepiece 1220 are disposed separately in the embodiment illustrated in FIGS. 27 and 28, embodiments of the present disclosure are not limited thereto. For example, the first eyepiece 1210 and the second eyepiece 1220 may be combined into one.

The first eyepiece 1210 may be aligned with the first display device 10_2 and the first optical member 1510, and the second eyepiece 1220 may be aligned with the second display device 10_3 and the second optical member 1520. Therefore, a user can view an image displayed by the first display device 10_2, which is enlarged as a virtual image by the first optical member 1510, through the first eyepiece 1210 and can view an image displayed by the second display device 10_3, which is enlarged as a virtual image by the second optical member 1520, through the second eyepiece 1220.

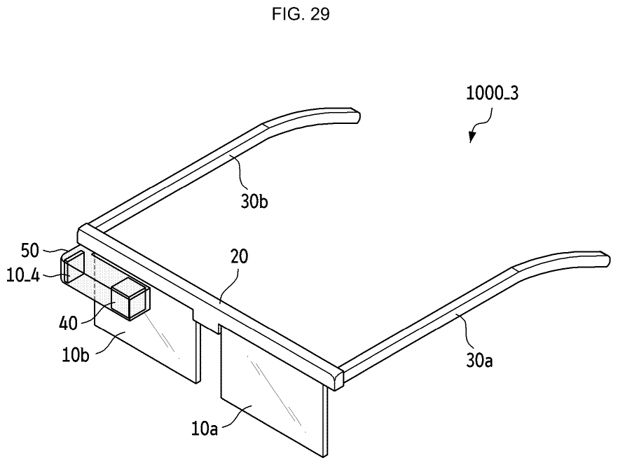

The head mounted band 1300 fixes the display device housing 1100 to a user's head so that the first eyepiece 1210 and the second eyepiece 1220 of the housing cover 1200 are kept placed on the user's left and right eyes, respectively. When the display device housing is implemented to be lightweight and small, the head mounted display device 1000_2 may have an eyeglass frame as illustrated in FIG. 29 instead of the head mounted band 1300.

In addition, the head mounted display device 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 29 is a perspective view of a VR device including a display device according to an embodiment. FIG. 29 illustrates a VR device 1000_3 to which a display device 10_4 according to an embodiment has been applied.

Referring to FIG. 29, the VR device 1000_3, according to an embodiment, may be a device in the form of glasses. The VR device 1000_3, according to the embodiment, may include the display device 10_4, a left lens 10a, a right lens 10b, a support frame 20, eyeglass frame legs 30a and 30b, a reflective member 40, and a display device housing 50.

In FIG. 29, an embodiment in which the VR device 1000_3 is a glasses-type display device including the eyeglass frame legs 30a and 30b is illustrated as an example. That is, the VR device 1000_3, according to the embodiment is not limited, to the one illustrated in FIG. 29 and can be applied in various forms to various other electronic devices.

The display device housing 50 may include the display device 10_4 and the reflective member 40. An image displayed on the display device 10_4 may be reflected by the reflective member 40 and provided to a user's right eye through the right lens 10b. Accordingly, the user may view a VR image displayed on the display device 10_4 through the right eye.

Although the display device housing 50 is disposed at a right end of the support frame 20 in FIG. 29, embodiments of the present disclosure are not limited thereto. For example, the display device housing 50 may also be disposed at a left end of the support frame 20. In such an embodiment, an image displayed on the display device 10_4 may be reflected by the reflective member 40 and provided to the user's left eye through the left lens 10a. Accordingly, the user may view a VR image displayed on the display device 10_4 through the left eye. In another embodiment, the display device housing 50 may be disposed at both the right end and the left end of the support frame 20. In such an embodiment, the user may view a VR image displayed on the display device 10_4 through both the left eye and the right eye.

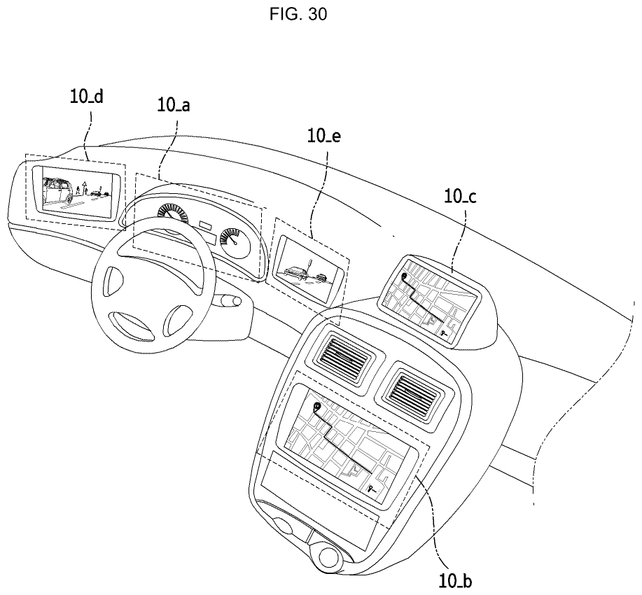

FIG. 30 is a view illustrating a vehicle instrument cluster and center fascia including display devices according to an embodiment. FIG. 30 illustrates a vehicle to which display devices 10_a through 10_e, according to an embodiment, have been applied.

Referring to FIG. 30, the display devices 10_a through 10_c, according to the embodiment, may be applied to an instrument cluster of the vehicle, a center fascia of the vehicle, or a center information display (CID) disposed on a dashboard of the vehicle. In addition, the display devices 10_d and 10_e, according to the embodiment, may be applied to room (or interior) mirror displays that replace side mirrors of the vehicle.

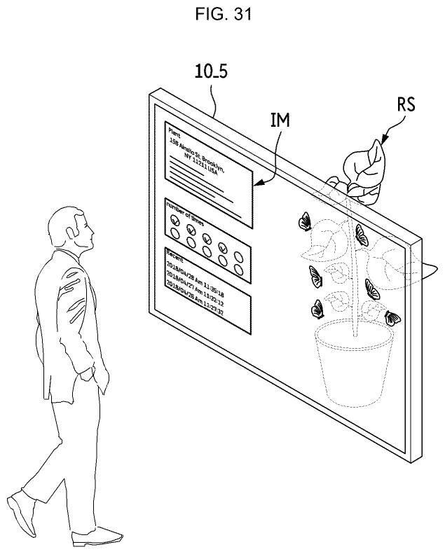

FIG. 31 is a view of a transparent display device including a display device according to an embodiment.

Referring to FIG. 31, a display device 10_5, according to an embodiment, may be applied to a transparent display device. The transparent display device may transmit light while displaying an image IM. Therefore, a user located in front of the transparent display device can view not only the image IM displayed on the display device 10_5 but also an object RS or the background located behind the transparent display device. When the display device 10_5 is applied to the transparent display device, a substrate of the display device 10_5 may include a light transmitting portion that can transmit light or may be made of a material that can transmit light.

In concluding the detailed description, those skilled in the art will appreciate that many variations and modifications can be made to the embodiments described herein without substantially departing from the spirit of the present disclosure. Therefore, the disclosed embodiments of the present disclosure are used in a generic and descriptive sense and not for purposes of limitation.

What is claimed is:

1. A display device comprising:
a substrate comprising a first organic film;
a plurality of pixel electrodes on the first organic film and aligned in a first direction and a second direction;
a common electrode on the first organic film, extending in the first direction, and aligned in the second direction;
a plurality of light emitting elements respectively on the pixel electrodes and the common electrode and aligned in the first direction and the second direction; and
a second organic film between the light emitting elements on the first organic film,
wherein the first organic film has a plurality of engraved lines extending in the first direction and between the light emitting elements, and
wherein the plurality of engraved lines are filled with the second organic film.

2. The display device of claim 1, wherein the plurality of engraved lines are below the light emitting element.

3. The display device of claim 1, wherein a width of the plurality of engraved lines is greater than a depth of the plurality of engraved lines.

4. The display device of claim 1, wherein the plurality of engraved lines have a cross-sectional shape of one of a right rectangle, an inverted triangle, an inverted trapezoid, and a semicircle.

5. The display device of claim 1, wherein each of the plurality of engraved lines has a same width.

6. The display device of claim 5, wherein from among the plurality of engraved lines, the width of the engraved line increases from the one of the engraved lines on an outer side of the substrate from another one of the engraved lines nearer a center of the substrate.

7. The display device of claim 1, wherein each of the plurality of engraved lines becomes wider from a center there to an edge thereof.

8. The display device of claim 1, wherein the light emitting element comprises,
a semiconductor stack,
a first contact electrode between one surface of the semiconductor stack and a corresponding one of the pixel electrodes, and
a second contact electrode between one surface of the semiconductor stack and the common electrode.

9. The display device of claim 1, wherein the second organic film is between the light emitting elements to flatten a step difference between the light emitting elements.

10. A method of manufacturing a display device comprising, the method comprising:
patterning an adhesive layer applied on an interposer into first areas and second areas;
patterning a plurality of engraved lines on a backplane mother substrate comprising a plurality of cell regions;
arranging the first areas of the interposer and the cell region of the backplane mother substrate to overlap; and
bonding a plurality of light emitting elements to the first area of the interposer such that the engraved line is between adjacent ones of the plurality of light emitting elements.

11. The method of claim 10, wherein the patterning of the adhesive layer comprises one of: removing the adhesive layer from the second areas, thinning a thickness of the adhesive layer from the second areas, and reducing an adhesive component of the adhesive layer in the second areas.

12. The method of claim 10, further comprising, before the bonding of the plurality of light emitting elements, disposing a plurality of light emitting elements into the first areas of the interposer.

13. The method of claim 10, wherein the first area has a size and area corresponding to a cell area of the backplane mother substrate.

14. The method of claim 10, further comprising, before the bonding of the plurality of light emitting elements:
forming a main alignment mark in an area adjacent to a vertex within the interposer; and
forming a sub-alignment mark in another area adjacent to each vertex of the first areas.

15. The method of claim 14, wherein the bonding of the plurality of light emitting elements comprises:
aligning the interposer on a backplane mother substrate by using the main alignment mark; and
transferring the plurality of light emitting element from the interposer onto a cell area of the backplane mother substrate by using the sub-alignment mark.

16. The method of claim 10, wherein the patterning of the plurality of engraved lines comprises patterning a plurality of engraved lines in a cell area of the backplane mother substrate by using a halftone mask.

17. The method of claim 10, wherein a bubble layer generated when the interposer is bonded to the backplane mother substrate is discharged along at least one of the plurality of engraved lines.

18. The method of claim 10, further comprising:
transferring the plurality of light emitting elements on the interposer to the backplane mother substrate; and
forming an organic film layer to flatten a step difference formed by the plurality of light emitting elements and filling the plurality of engraved lines with the organic film layer.

19. A display device comprising:
a substrate comprising a first organic film;
a plurality of pixel electrodes on the first organic film;
a plurality of light emitting elements respectively on the pixel electrodes;
a second organic film between the light emitting elements on the first organic film; and
a common electrode on the light emitting elements and the second organic film,
wherein the first organic film has a plurality of engraved lines extending in a first direction and arranged between the light emitting elements, and
wherein the plurality of engraved lines are filled with the second organic film.

20. The display device of claim 19, wherein a width of the plurality of engraved lines is greater than a depth of the plurality of engraved lines.

21. A wearable device comprising a display device,
wherein the display device comprises:
a substrate comprising a first organic film;
a plurality of pixel electrodes on the first organic film and aligned in a first direction and a second direction;
a common electrode on the first organic film, extending in the first direction, and aligned in the second direction;
a light emitting element on the pixel electrode and the common electrode and aligned in the first direction and the second direction; and
a second organic film between the light emitting elements on the first organic film,
wherein the first organic film of the display device has a plurality of engraved lines extending in the first direction and between the light emitting elements, and
wherein the plurality of engraved lines of the display device are filled with the second organic film.
